(19) United States
(12) Patent Application Publication
(10) Pub. No.: US 2024/0085785 A1
(43) Pub. Date: Mar. 14, 2024

(54) ADDITIVES FOR METAL OXIDE PHOTORESISTS, POSITIVE TONE DEVELOPMENT WITH ADDITIVES, AND DOUBLE BAKE DOUBLE DEVELOP PROCESSING

(71) Applicants: Inpria Corporation, Corvallis, OR (US); JSR Corporation, Tokyo (JP)

(72) Inventors: Kazuki Kasahara, Corvallis, OR (US); Brian J. Cardineau, Corvallis, OR (US); Kai Jiang, Corvallis, OR (US); Stephen T. Meyers, Corvallis, OR (US); Amrit N. Narasimhan, Corvallis, OR (US); Matthew Voss, Corvallis, OR (US)

(21) Appl. No.: 18/233,932

(22) Filed: Aug. 15, 2023

Related U.S. Application Data
(60) Provisional application No. 63/398,723, filed on Aug. 17, 2022.

(51) Int. Cl. G03F 7/004

(52) U.S. Cl. CPC G03F 7/0044; G03F 7/0045; G03F 7/38

(57) ABSTRACT

A method for patterning a radiation sensitive material on a substrate involves the development of a material on a substrate based on a latent image in the material with irradiated regions and non-irradiated regions to form a physically patterned material on the substrate, in which the material comprises an organotin radiation sensitive patterning material and an additive. The additive is a photoacid generator, a quencher or a mixture thereof. Patterning improvements can be achieved using a series of a baking and development step followed by a second baking at a higher temperature and a second development step following the second baking step. A precursor solution for forming an organometallic radiation patterning material can comprise an organic solvent, a dissolved organotin composition having C—Sn bonds that can cleave in response to EUV radiation, and a quencher. The additive can comprise an onium cation.

### CROSS REFERENCE TO RELATED APPLICATIONS

This application claims priority to copending U.S. provisional patent application 63/398,723 filed on Aug. 17, 2022 to Kasahara et al., entitled “Electron Trapping Agents for Metal Oxide Photoresists,” incorporated herein by reference.

### FIELD OF THE INVENTION

The invention relates to organometallic, in particular organotin, patterning compositions with additives, such as photoacid generators and/or quenchers to improve development process conditions. Specifically, the additives can particularly improve positive tone imaging through an expansion of the process window associated with the radiation dose. A development procedure involving sequential Bake-Develop-Bake-Develop is described, which can benefit from the presence of the additives.

### BACKGROUND OF THE INVENTION

Semiconductor lithography is a complex and critical technology used to fabricate myriad and diverse devices that have dominated and transformed the modern world beginning in the 20^{th} century. The semiconductor lithographic process is generally an iterative process involving repeated steps of deposition, patterning, and etching of many layers and materials to form the desired devices. As technology advances and new, increasing demands and requirements are placed upon each generation of devices, the need to develop processes and materials that are able to meet these requirements increases. One of the critical materials used in the semiconductor lithographic process is the photoresist in which an initial pattern is formed by exposure to radiation and is then subsequently transferred into the underlying substrate.

Organometallic photoresists have been shown to be promising materials for use in current and next-generation semiconductor lithography processing due to their ability to form high-resolution, high etch resistance, and high-fidelity patterns. These organometallic systems generally operate through radiation exposure-mediated formation of condensed oxide networks that drive contrast between irradiated (i.e., exposed) and non-irradiated (i.e., unexposed) regions of the material. A development process can then be used that can selectively remove the irradiated or the non-irradiated material to realize a physical pattern of material based on the pattern of radiation.

Due in part to their high absorbance of extreme ultraviolet (EUV) radiation and propensity to form oxide/hydroxide networks, organometallic resists can absorb stray photons, such as from “shot noise” phenomena, in nominally non-irradiated (i.e., unexposed) regions which can lead to undesired photochemistry in those regions which can, in turn, can lead to defects such as scum or microbridging between features. The current invention describes improvements to organometallic photoresist compositions that comprise electron-trapping agents to reduce defect formation and improve patterning performance.

### SUMMARY OF THE INVENTION

One aspect of the invention pertains to precursor compositions comprising one or more organotin compositions, an electron-trapping agent, and a solvent.

Another aspect of the invention pertains to radiation-patternable films comprising organotin species and an electron-trapping agent.

Another aspect of the invention pertains to a structure comprising a radiation-sensitive layer, which may be patterned, comprising an organotin species and an electron-trapping agent.

Another aspect of the invention pertains to a method for patterning a structure comprising a radiation-sensitive layer comprising an organotin species and an electron-trapping agent.

In a particular aspect, the invention pertains to a method for patterning a radiation sensitive material on a substrate, in which the method comprises developing a material on a substrate based on a latent image in the material with irradiated regions and non-irradiated regions to form a physically patterned material on the substrate. The developing can comprise contact of the material with an aqueous alkaline liquid, and the material prior to irradiation comprises an organotin composition represented by RₙSnOₓ(OH)₄₋ₙ₋₂ₓ, 0.5≤n<3, 0<x<1.5, wherein R comprises a hydrocarbyl ligand having from 1-31 carbon atoms, and an additive (A) in a molar ratio of A:Sn from about 0.002 to about 2. The additive comprises a photoacid generator, a quencher, or a mixture thereof, in which the additive comprises an onium ion or zwitterion. The developing involves selective removal of the irradiated regions.

In a further aspect, the invention pertains to a method for patterning a radiation sensitive material on a substrate, in which the method comprises:
a) developing a material on a substrate based on a latent image in the material with irradiated regions and non-irradiated regions to form a physically patterned material on the substrate. The developing comprises contact of the material with a first liquid developer, and the material prior to irradiation comprising RₙSnOₓ(OH)₄₋ₙ₋₂ₓ 0.5≤n<3, 0<x<1.5, wherein R comprises a hydrocarbyl ligand having from 1-31 carbon atoms. The substrate with the latent image received a post exposure bake at a first temperature at least about 45° C. The developing comprises selective removal of the irradiated regions or the non-irradiated regions to form a first patterned structure;
b) heating the first patterned structure at a second temperature at least about 5° C. greater than the first temperature for at least about 0.1 minute to form a second baked structure, and
c) developing the second baked structure comprising contact with a second liquid developer, wherein the second liquid developer comprises an acid or a base.

In another aspect, the invention pertains to a precursor solution for forming an organometallic radiation patterning material, the precursor solution comprising an organic solvent, a dissolved organotin composition having C—Sn bonds that can cleave in response to EUV radiation, and a quencher, in which the precursor solution has a tin concentration from about 0.001 M to about 1 M and the quencher (A) in a molar ratio of A:Sn from about 0.002 to about 2, and the quencher comprises an onium cation and an anion that is a conjugate base to a weak acid.

In other aspects, the invention pertains to a radiation patternable structure comprising a substrate and a radiation sensitive material on the substrate. The radiation sensitive material comprising a composition represented by the formula RₙSnOₓ(OH)₄₋ₙ₋₂ₓ 0.5≤n<3, 0<x<1.5, and a quencher (A) in a molar ratio of A:Sn from about 0.002 to about 2. The quencher generally comprises an onium cation and an anion that is a conjugate base to a weak acid.

### DESCRIPTION OF THE FIGURES

FIG. 1A is a schematic side-view of an exposure process using a photomask wherein the mask creates an aerial image of photons delivered to the surface of the photoresist.

FIG. 1B is a cartoon of a top-down view of photon distribution across the surface of the photoresist according to the mask pattern.

FIG. 1C is a schematic side-view of the density distribution of photons for the latent image according to the mask pattern.

FIG. 2A is a schematic plot of the solubility of the photoresist across the pattern dimension juxtaposed on the intended line/space pattern of the mask pattern.

FIG. 2B is a modification of the plot of FIG. 2A depicting the solubility of the photoresist with an organic developer across the pattern dimension juxtaposed on the intended line/space pattern of the mask pattern, and highlights a region of the pattern that may result in unintended insolubility in the dark region of the pattern.

FIG. 2C is a modification of the plot of FIG. 2A depicting the solubility of the photoresist with an alkaline developer across the pattern dimension juxtaposed on the intended line/space pattern of the mask pattern, and highlights a region of the pattern that may result in unintended insolubility in the irradiated region of the pattern.

FIG. 3 is a cartoon of a contrast curve for positive-tone patterning showing polarity-dominated and density-dominated regions.

FIG. 4 is an illustration of a first contrast curve (solid lines) and a second contrast curve (dashed lines), with the second contrast curve having a wider solubility window.

FIG. 5 is an illustration of the low dose region of a first contrast curve (dashed lines) and a second contrast curve (solid lines), with the second contrast curve showing a shift to a lower solubility dose than the first contrast curve, as depicted by the arrow.

FIG. 6 is an illustration of the high dose region of a first contrast curve (dashed lines) and a second contrast curve (solid lines), with the second contrast curve showing a shift to a higher solubility dose than the first contrast curve, as depicted by the arrow.

FIG. 7 is an illustration of a first contrast curve (dashed lines) and a second contrast curve (solid lines), with the second contrast curve having a widened process window for positive tone patterning.

FIG. 8 is an illustration of contrast curve changes in the low dose and the high dose regions with the use of a double bake double development (DBDD) process.

FIG. 9 is an illustration of the high dose region of a first contrast curve after a single bake and single development and the high dose region of a second contrast curve after a double bake double development (DBDD) process.

FIG. 10A is a set of contrast curves for photoresist samples prepared with various concentrations of A1 additive, each sample having been subjected to a 120° C. PEB.

FIG. 10B is a set of contrast curves for photoresist samples prepared with various concentrations of A1 additive, each sample having been subjected to a 140° C. PEB.

FIG. 10C is a set of contrast curves for photoresist samples prepared with various concentrations of A1 additive, each sample having been subjected to a 160° C. PEB.

FIG. 10D is a set of contrast curves for photoresist samples prepared with various concentrations of A1 additive, each sample having been subjected to a 180° C. PEB.

FIG. 10E is a set of contrast curves for photoresist samples prepared with various concentrations of A1 additive, each sample having been subjected to a 200° C. PEB.

FIG. 10F is a set of contrast curves for photoresist samples prepared with various concentrations of A1 additive along with a non-additive control sample, each sample having been subjected to a 180° C. PEB.

FIG. 11A is a set of contrast curves for photoresist samples prepared with A4 additive and subjected to various PEB temperatures from 120° C. to 180° C.

FIG. 11B shows contrast curves for a photoresist sample prepared with an A4 additive a photoresist sample prepared without the additive, each sample having been subjected to a 140° C. PEB.

FIG. 11C shows contrast curves for a photoresist sample prepared with an A4 additive a photoresist sample prepared without the additive, each sample having been subjected to a 160° C. PEB.

FIG. 11D shows contrast curves for a photoresist sample prepared with an A4 additive a photoresist sample prepared without the additive, each sample having been subjected to a 180° C. PEB.

FIG. 12 is a plot of normalized alkyl content as a function of dose for two photoresist samples prepared with an A4 additive and one photoresist sample prepared without the additive, with the samples in the left plot having been subjected to a 160° C. PEB and with the samples in the right plot having been subjected to a 180° C. PEB.

FIG. 13A is a set of contrast curves for photoresist samples prepared with various concentrations of A2 additive, each sample having been subjected to a 120° C. PEB.

FIG. 13B is a set of contrast curves for photoresist samples prepared with various concentrations of A2 additive, each sample having been subjected to a 140° C. PEB.

FIG. 13C is a set of contrast curves for photoresist samples prepared with various concentrations of A2 additive, each sample having been subjected to a 160° C. PEB.

FIG. 13D is a set of contrast curves for photoresist samples prepared with various concentrations of A2 additive, each sample having been subjected to a 180° C. PEB.

FIG. 13E is a set of contrast curves for photoresist samples prepared with various concentrations of A2 additive, each sample having been subjected to a 200° C. PEB.

FIG. 13F is a set of contrast curves for photoresist samples prepared with various concentrations of A2 additive along with a non-additive control sample, each sample having been subjected to a 180° C. PEB.

FIG. 14A is a set of contrast curves for photoresist samples prepared with various concentrations of A3 additive, each sample having been subjected to a 120° C. PEB.

FIG. 14B is a set of contrast curves for photoresist samples prepared with various concentrations of A3 additive, each sample having been subjected to a 140° C. PEB.

FIG. 14C is a set of contrast curves for photoresist samples prepared with various concentrations of A3 additive, each sample having been subjected to a 160° C. PEB.

FIG. 14D is a set of contrast curves for photoresist samples prepared with various concentrations of A3 additive, each sample having been subjected to a 180° C. PEB.

FIG. 14E is a set of contrast curves for photoresist samples prepared with various concentrations of A3 additive, each sample having been subjected to a 200° C. PEB.

FIG. 14F is a set of contrast curves for photoresist samples prepared with various concentrations of A3 additive along with a non-additive control sample, each sample having been subjected to a 180° C. PEB.

FIG. 15 is a set of contrast curves for photoresist samples prepared without an additive and subjected to either a single PEB and development process or a double bake and double development (DBDD) process. The samples subjected to a DBDD process were processed with various first PEB temperatures and a constant second PEB temperature.

FIG. 16 is a set of contrast curves for photoresist samples prepared with additive A2 and subjected to either a single PEB and development process or a double bake and double development (DBDD) process. The samples subjected to a DBDD process were processed with the same first PEB temperatures and a different second PEB temperature. A contrast curve for a photoresist sample prepared without an additive and subject to a single PEB and development process is also shown.

FIG. 17 shows a set of CD-SEM images of contact holes patterned into either a photoresist sample without an additive or a photoresist sample with additive A2, each sample having been subjected to either a 160° C. PEB or a 180° C. PEB.

FIG. 18 shows two CD-SEM images of contact hole patterns prepared using photoresist samples with an A2 additive, each sample having been subjected to a double bake double development process.

FIG. 19 shows a set of CD-SEM images of contact holes patterned into a photoresist sample without an additive or a photoresist sample with additive A2, each sample having been subjected to either a single PEB and development process or a double bake double development process.

FIG. 20 shows a set of CD-SEM images of contact holes patterned into a photoresist sample without an additive or a photoresist sample with a quencher additive, each sample having been subjected to either a 160° C. PEB or a 180° C. PEB.

### DETAILED DESCRIPTION OF THE INVENTION

The patterning of organometallic photoresists can be improved in some circumstances by the presence of an additive, specifically a photoacid generator and/or a quenching agent, in the photoresist film to reduce blurring of a pattern provided by radiation patterning. The additives can absorb photons and/or photoelectrons (secondary electrons) in so-called “dark regions” of the film, regions which are nominally unexposed to radiation, with or without the release of a proton. In particular, effective exposure in dark regions can result in reaction of the organometallic composition resulting in blurring. The improvements resulting from the additives are particularly effective in the context of positive tone patterning. In a typical lithography process, an aerial pattern of radiation is directed to the photoresist by the use of a mask that renders the pattern to create exposed and unexposed regions of the photoresist. However, photons generally follow a distribution, which may approximate a Poisson distribution, across the boundary between exposed and unexposed regions of the pattern, and the number of photons penetrating the photoresist material in the nominally “unexposed” regions can be non-zero. The spreading of the radiation pattern at the boundary exacerbates the range of secondary electrons that can further blur the image. Additives blended with the radiation sensitive organometallic composition can capture, trap, or react with the secondary electrons and can effectively reduce the likelihood of electrons reacting with the organometallic compositions. The additives can be selected to primarily absorb in the UV away from the EUV so that these agents can be used for EUV patterning without significantly competing with the organometallic patterning composition for EUV light. Thus, the additive does not lower the efficiency of the EUV patterning while scavenging secondary electrons to reduce blurring. For negative-tone embodiments, both the additive and its product after electron capture can be soluble in a suitable solvent, such as a developer and/or a rinse composition. The quenching of secondary electrons can be useful to reduce line roughness, decrease processing steps to sharpen feature edges, and/or to increase development efficacy.

Significant edge blurring can occur in EUV photolithography from shot-noise and secondary electrons. EUV radiation for photolithography is generated with a plasma source that has a three-dimensional spatial distribution without sharp edges to the pattern. The “masking” is generally performed with appropriately patterned mirrors that may sharpen the light output somewhat. While efforts have been proposed to improve the “masking”, the irradiation with EUV radiation has a radiation distribution at the edges. See, for example, U.S. Pat. No. 10,890,849 to Flagello et al., entitled “EUV Lithograph System for Dense Line Patterning,” incorporated herein by reference. In addition to shot noise from the masking and irradiation process directly, secondary electrons and redirected light can result in effective irradiation of the material deeper into the “dark-regions” of the material.

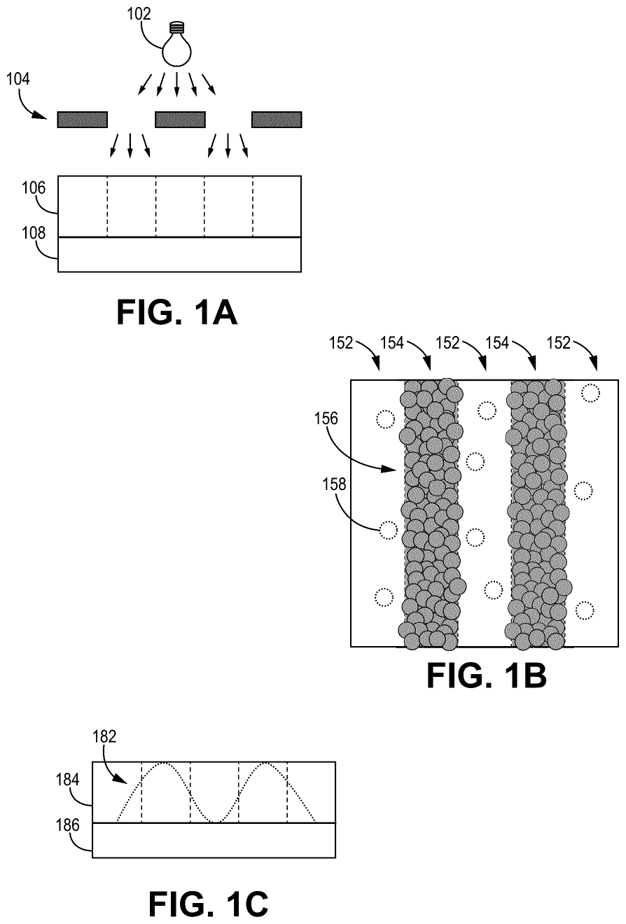

FIG. 1A is a schematic side-view of an exposure process in which radiation source 102 is directed onto photomask 104. Photomask 104 creates an aerial image of photons delivered to the surface of photoresist 106 on substrate 108. As illustrated in FIGS. 1B-1C, the photon density distribution for a line-space pattern is not a square wave but rather a distribution across the exposed and unexposed regions. As an example, FIG. 1B shows a cartoon of a top-down view of the photons delivered to the surface of the photoresist where photons 156, the majority of the photons fall, or impact upon, the surface of the photoresist in regions of the pattern 154 according to the pattern of radiation, but some number of stray photons 158 (i.e., “shot-noise” photons) fall in regions of the pattern 152 intended to be shaded from the exposure radiation. In another illustrative example, FIG. 1C shows a side-view of distribution of photons 182 across patterned latent image 184 in the photoresist on substrate 186 where the density of photons impacting the resist roughly follows the mask pattern, but some photon density can be present within the dark regions of the associated mask pattern. These photons can then be absorbed in such regions to result in photochemical reactions that can change the solubility of species within the unexposed regions to lead to exposure products that are similar in character, but not scale, as to the photochemical reactions occurring the exposed regions.

Organotin photoresists are known to generally operate by the presence of radiation sensitive tin-carbon bonds that can stabilize the photoresist film against rampant condensation to yield a relatively low -density oxide material, while also imparting hydrophobicity to the material due to the presence of organic groups. Upon exposure to radiation and/or heating at elevated temperatures, the tin-carbon bond is cleaved and condensation/densification can occur between adjacent tin centers to afford a more oxide-rich material. In this way, suitable developers can extract the chemical contrast between exposed and unexposed regions of the photoresist film by selectively acting on the exposed or unexposed regions in a negative-tone or positive-tone process. For example, the unexposed material is generally soluble in organic-based solvents, whereas the exposed material is generally soluble in aqueous-based acidic or alkaline solvents. Other development processes, such as thermal or “dry” development processing, can be used wherein a plasma or vapor flow can be used to remove unexposed material.

The additives can be introduced to the photoresist compositions during formulation of the photoresist precursor solutions for introduction into patterning materials on a substrate. Organotin photoresists generally comprise one or more hydrolytically sensitive organotin species represented by the formula RₙSnL₄₋ₙ, where n=0.5-3 (or in further embodiments n=0.75-2.0, where n is an average for the species present), and L is a ligand that forms a hydrolysable bond with the Sn, such as a dialkylamide (—NR′₂), an alkoxide (—OR′), an acetylide (—CCR′), a carboxylate (—COOR′), and/or the like. In some cases, organotin photoresists can comprise cluster or nanoparticle compositions where multiple RSn moieties are linked through Sn—O—Sn, Sn—OH—Sn, or Sn—COO—Sn bonds such as, for example, in the dodecameric “football” clusters [(RSn)₁₂O₁₄(OH)₆]²⁺ and the hexameric “drum” clusters [RSnOOCR′]₆. These organotin compositions are generally dissolved in appropriate solvents to form organotin photoresist solutions. The additives, which are generally effective as electron-trapping agents, can be dissolved in these organotin photoresist solutions. In some embodiments, the additives can be added to and/or dissolved in the organotin photoresist composition. In other embodiments, the additives can be added to and dissolved into a solvent to form an additive solution that can then be combined with the organotin photoresist solution.

Organotin materials are known to display dual tone patterning behavior wherein the desired tone of patterning can be selected by appropriate choice of developer. The patterning material chemistry results in an increase of the metal oxide character of the irradiated material in contrast with the more organic nature of the non-irradiated patterning material. For example, organic-based developers generally result in negative tone patterning of the organotin materials wherein the unexposed material is removed from the substrate during development. Conversely, positive-tone patterning can be achieved through development with aqueous base developer compositions. Negative tone patterning involves a removal of the non-irradiated material, so dark region irradiation can frustrate removal of material. Positive tone patterning involves removal of the irradiated material, so dark region irradiation can result in some removal of “non-irradiated” material. Due to blurring at the edges and irradiation from secondary electrons, various effects exacerbate difficulties in obtaining a sharp pattern edge.

The dual tone nature of organotin patterning materials can be understood by the chemical nature of the material before and after exposure to a suitable radiation source. As described herein and in Applicant's previous patents cited below (to Meyers, et al.), photoresist films comprising organotin materials are generally prepared from deposition of one or more organotin precursor compounds that are generally represented by the formula RₙSnL₄₋ₙ wherein R is an hydrocarbyl ligand, L is a hydrolysable ligand, and n can generally be an integer from 0 to 4 that represents the number of hydrocarbyl groups bound to the Sn atom. Detailed options for the R groups are presented below. Generally, the overall stoichiometry generally has 0.5≤n<3, and desirable patterning results have been obtained with n=1. These organotin precursor compounds can be hydrolyzed during a deposition process to hydrolyze the hydrolysable ligands while leaving the R—Sn bonds intact while driving condensation between Sn atoms to form a film comprising an organometallic oxide hydroxide network represented by the formula RSnO(OH), where n=1 relative to the above general formula.

The film therefore comprises hydrophobic RSn moieties that can be solubilized by organic developers. During exposure to ionizing radiation, R—Sn bonds are broken, and cleaved hydrophobic R groups are liberated from the film to leave a more polar and hydrophilic irradiated material that can then be removed by aqueous base developers. The removal of the R-groups can be monitored spectroscopically. The polarity difference between irradiated and non-irradiated material thus enables dual tone patterning through appropriate choice of developer. Around the pattern edges, there is an effective gradient in irradiation, which can be thought of as a gradient in dose relative to the dose received at the center of the irradiated region. In this way, the dose dependent patterning behavior at the center of the pattern provides useful insight into the patterning at the edges.

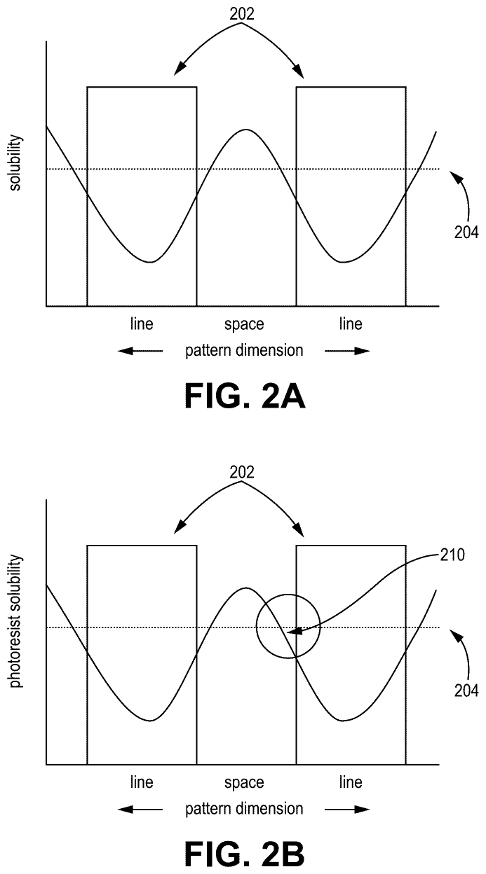

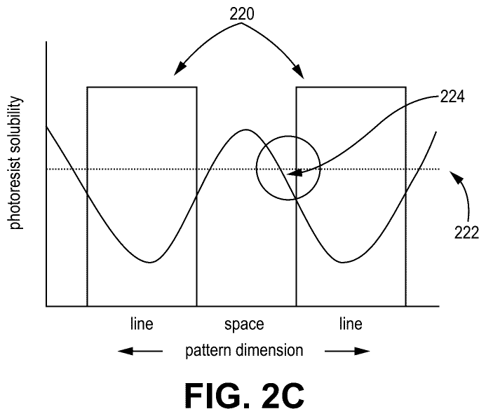

Referring to FIG. 2A, a plot of solubility vs. the pattern position (e.g., according to the aerial image) illustrates that solubility is generally minimized in irradiated regions of the pattern 202 (e.g., the lines), and generally maximized in the non-irradiated regions of the pattern (e.g., the spaces). Some solubility threshold 204 is generally needed to prevent removal of the irradiated regions such that a negative-tone pattern can be realized. However, as described above, some shot-noise photons can be absorbed in the dark regions of the pattern, such as region 210, to result in insoluble photoproducts that may be difficult to remove during a development process and can therefore remain part of the pattern as defects, particularly if the number of photochemical events in the dark regions of the pattern drive a decrease in solubility near to or exceeding that of the solubility threshold, as described in FIG. 2B. Referring to FIG. 2C, a plot of solubility vs. the pattern position with a positive tone developer, illustrates that solubility is generally eliminated in un-irradiated regions of the pattern 220 (e.g., the lines), and generally significant in the irradiated regions of the pattern (e.g., the spaces). Some solubility threshold 222 is generally present to avoid removal of the un-irradiated regions such that a positive-tone pattern can be realized. However, as described above, some shot-noise photons can be absorbed in the non-irradiated regions of the pattern, such as region 224, to result in soluble photoproducts that may be difficult to distinguish during a development process.

The absorbed EUV photons can cleave carbon-tin bonds to result in condensation of the material. As suggested above, side-effects of the EUV irradiation include the production of high energy primary photoelectrons which in turn result in the generation of lower energy secondary electrons through scattering and/or ionization mechanisms in a process generally referred to as a secondary electron cascade. The secondary electrons can be considered to radially disperse around the point of initial absorption. Interaction of the organotin patterning material with the secondary electrons can also result in cleavage of the carbon-tin bond and, depending on the mean free path of the electrons, the secondary electrons create a blurring of the radiation pattern that extends potentially further than the shot-noise. This is shown schematically in FIGS. 2A to 2C. To the extent that the secondary electrons are deeply penetrating (FIG. 2A), condensation of the non-irradiated region can result in more scum formation in negative patterning and a generally loss of depth of the remaining material for positive patterning. If the pattern dimensions are large enough that the secondary electrons do not penetrate through the whole pattern (FIG. 2B—negative tone patterning and FIG. 2C—positive tone patterning), then the line edges still blur more than from shot-noise alone.

The additives described herein are photoacid generators and/or quenchers, are generally organic, and suitable chemical compositions are described further below. While the additives and any reaction products of the additives would be soluble in organic solvents, presence of the additives in the patterning composition can interfere with condensation of the irradiated material. Corresponding to the effective slope of photon intensity at the pattern edges, the solubilities similarly slope so that edge blurring takes place. In a sense, the variation in photon intensity corresponds with different physical positions effectively experiencing different sections of the dose plot with the corresponding blurring being observed.

With negative tone patterning, irradiation results in a loss of organic ligands such that the irradiated material becomes insoluble in organic solvents. During development the non-irradiated material is removed. Since the additive is an organic composition, the presence of the additive tends to promote the use of a higher radiation dose to achieve a desired degree of condensation of the irradiated material. The inclusion of PAGs in organotin resists has been described as contributing to the achievement of lower line edge roughness in negative tone development, see published U.S. patent application 2021/0311387 to Woo et al., entitled “Semiconductor Photoresist Composition and Method of Forming Patterns Using the Composition,” incorporated herein by reference. The presence of the additives though presents a tradeoff for negative tone patterning, and Applicant has not found any significant, consistent improvement with the inclusion of PAG or quencher additives for general negative tone patterning, although a double bake-double develop process is described below that can effectively improve negative tone patterning with the additives.

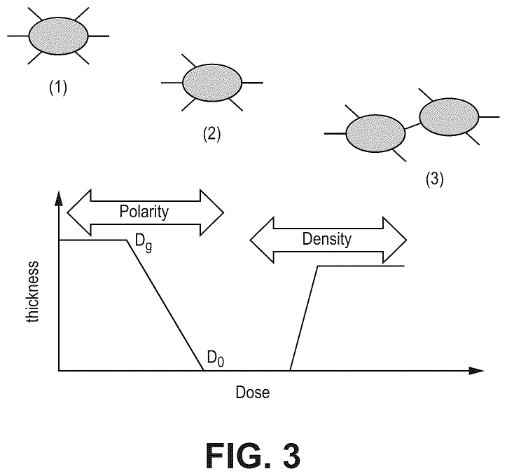

While positive-tone patterning can be achieved with organotin materials, the window for suitable positive-tone patterning is generally limited by the degree of condensation (i.e., density) of the irradiated material. For illustrative purposes, a schematic contrast curve for positive-tone patterning in an aqueous base is presented in FIG. 3, where thickness remaining after development is plotted against the dose delivered to the photoresist. Since a delivered dose to a wafer is the maximum in the illuminated zone, it can be presumed in the plot of FIG. 3 that the relevant measurements are made at the center of the pattern if the dose is considered as a reported dose for a patterning experiment. But due to an effective drop in dose near the pattern boundaries, the dose plot also provides valuable information spatial effects on development to remove material based on a virtual image.

As illustrated in FIG. 3, as the dose delivered to the photoresist increases and dealkylation occurs via cleavage of R—Sn bonds, the irradiated material becomes soluble in developer, and the material can be substantially removed from the substrate. Specifically, as dealkylation occurs, the polarity of the irradiated material increases relative to the non-irradiated material, and the material becomes soluble in aqueous base developer. However, as the dose continues to increase further and the material becomes highly irradiated, the density and degree of condensation increases and the developer is no longer able to selectively remove the material. It is therefore desirable to improve the solubility of the irradiated material in a positive tone developer and thereby improving the positive-tone process window. A wider process window is generally desirable for providing for relaxed dose and temperature requirements, allowing for positive-tone patterning to be successfully achieved at more conditions.

As described herein, the presence of suitable additives comprising photoacid generators (PAGs) and/or quenchers can improve the patterning of organotin materials. In particular, improvements are found for positive-tone patterning, and the effects can be exploited effectively using a double-bake+double develop processing described below. The improvements to positive tone processing can be achieved by the addition of additives that can improve the solubility of irradiated material in an aqueous developer (e.g., condensation inhibitors), reduce D₀ (the minimal dose needed to remove the material), and/or improve the contrast of positive-tone development. These changes become manifested in the contrast curves.

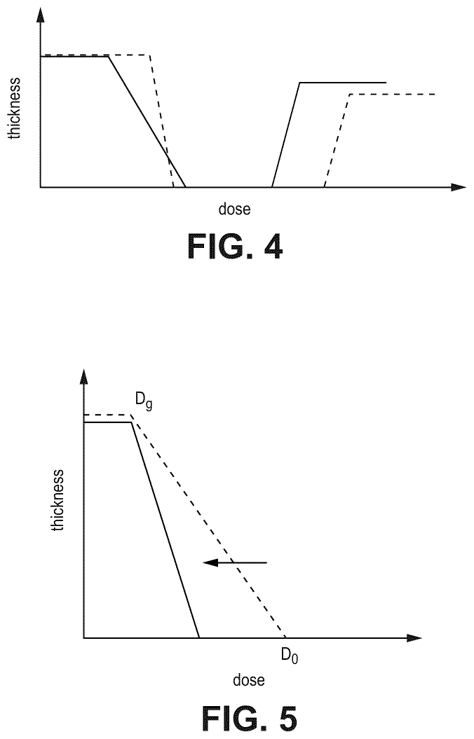

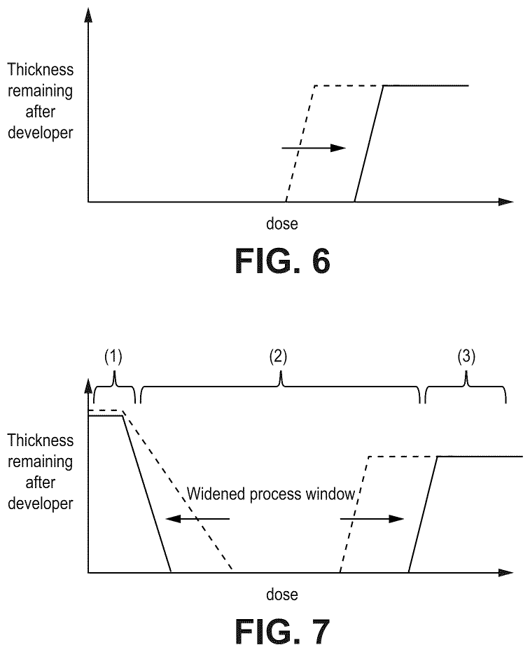

Referring to FIG. 4, objectives are to steepen the leading edge of the dose curve so that once the irradiated resist starts to become soluble, a further modest increase in dose can result in complete removal of the irradiated material due to decreased condensation providing more effective exploitation of the solubility changes by the developer. See FIG. 5. With respect to further increasing dose, the presence of the additive reduces condensation so that a higher dose can be applied before the condensation is excess enough to inhibit development. See FIG. 6. The overall effects are summarized in FIG. 7. Zone 1 depicts a low dose region where the patterning material is lightly exposed, hydrophobic, and insoluble. Zone 2 depicts the process window region where the material is moderately exposed, low density SnOSn network, and soluble. Zone 3 depicts development of material that is highly exposed, high density SnOSn, and insoluble.

In some embodiments, suitable additives can comprise photoacid generators (PAGs). While not wanting to be limited by theory, evidence suggests that the presence of PAGs within the organotin matrix can improve the susceptibility of dealkylation of the organotin species after EUV exposure and during a post exposure bake (PEB) step by promoting radiolysis induced thermolysis. During exposure to radiation, Sn—C bonds are cleaved within the irradiated material. It has been discovered that the thermal stability of the hydrocarbyl compounds remaining in the material after irradiation is significantly reduced, and their thermal stability decreases with decreasing Sn—C concentration. In other words, as the concentration of Sn—C bonds in the irradiated material is reduced, the thermal stability of the remaining Sn—C bonds in the irradiated material is also reduced. Therefore, and as shown in the Examples below, after exposure to radiation where an initial amount of Sn—C bonds are cleaved, a subsequent bake can drive further cleavage of Sn—C bonds via thermolysis in a phenomenon referred to as a radiolysis induced thermolysis process. The radiolysis induced thermolysis phenomenon can enable improved processing methods for the materials described herein, such as processing involving multiple bakes and multiple developments.

As shown in the Examples below, the presence of PAGs in the photoresist can improve the efficiency of the radiolysis induced thermolysis process by improving the amount of thermolysis (i.e., cleavage of Sn—C bonds via heating) during a bake process following exposure to radiation. While not wanting to be limited by theory, it is believed that the generation of photoacids during radiation exposure can promote stabilization of fragments resulting from the cleavage of Sn—C bonds during irradiation and/or a subsequent baking process. Organotin compositions comprising PAGs can therefore lead to improved solubility of exposure products in positive tone developers.

In some embodiments, suitable additives can comprise quenchers, which can neutralize acidic protons. As described further below, both PAGs and quenchers may act as electron trapping agents. Thus quenchers, as well as PAGs, within the photoresist film can absorb photons and/or secondary electrons to limit spatial spreading of C—Sn bond cleavage. Since quenchers neutralize acidic protons, quenchers yield photoproducts that do not significantly alter the radiolysis of the organotin materials within the irradiated regions of the photoresist.

In the irradiated regions of the photoresist, many photons are absorbed to create a cascade of secondary electrons that can lead to decomposition of the tin-carbon bonds within the material. However, in the non-irradiated regions, the photons impacting the material are fewer in number and the secondary electrons generated can be significantly “quenched” by the presence of the electron trapping agents, thereby reducing the number of tin-carbon bond cleavage events that would otherwise lead to irradiation products in dark regions that result in defects. The use of organotin photoresist compositions comprising electron-trapping agents can modify the solubility profile of the photoresist such that the nominally non-irradiated dark regions of the pattern show increased solubility. In other words, the number of photochemical events leading to insoluble species that occur from absorption of shot-noise photons can be reduced in organotin photoresist compositions comprising electron-trapping agents.

Additionally, the additive compositions described herein can be useful for improving the positive tone process window of organotin photoresists. After radiation exposure and subsequent baking, the radiation-sensitive hydrocarbyl ligands are cleaved and removed from the film to result in irradiated regions that comprise a condensed oxide hydroxide network. As the radiation dose and/or PEB temperature increases, more of the hydrocarbyl ligands are removed from the film and the degree of condensation and/or density of the oxide hydroxide network increases. For conventional patterning tone processing of organotin materials, at high doses and/or PEB temperatures the resulting oxide hydroxide network can condense/densify to such an extent as to become insoluble in aqueous base developers. The use of the additive compositions described herein can inhibit the condensation processes that occur at higher doses and can improve the solubility of the irradiated regions in aqueous base developer.

Positive tone patterning of organotin materials is enabled by radiation-induced polarity changes in the photoresist film. The inclusion of organic-based hydrophobic additives in organotin photoresist compositions can be useful for improving the solubility of radiation exposed products while not significantly increasing the solubility of unexposed and/or lightly exposed material. Conversely, the presence of such additives in organotin photoresist films can interfere with condensation and oxide hydroxide network formation after irradiation and/or baking and can therefore lead to improved solubility of the photoresist at higher doses. In this way, the positive tone patterning process window (i.e., the doses at which the photoresist is soluble) can be improved.

The effects of the additives can be exploited in the context of a sequential development in which a first PEB is performed with a development, followed by a second PEB at a higher temperature followed by a second development step. This double bake-double development (DBDD) procedure can be effectively applied for either positive tone or negative tone processing. The second bake step after the first development step is believed to result in further release of organic species from the irradiated material so that the material can further condense.

For positive tone development, the reduced condensation induced by the additive provides for opening up the higher dose edge of the process window, and can be particularly advantageous for a DBDD process. For example, if a somewhat lower temperature is used for the first PEB, the irradiated material is not as condensed and can be substantially removed in a first development with an aqueous base. When the second PEB is performed at the greater temperature, and since the high dose exposure material would have been substantially removed already, the further condensation afforded by the second PEB would not be detrimental to the process window. The second PEB, however, can drive dealkylation and condensation of the material near D₀, increasing this material's solubility in aqueous base developer, and thus providing for widening of the process window and improved positive-tone contrast. Thus, overall the DBDD process allows for widening the process window for positive development by lowering the dose required to render the material soluble in aqueous base developer (such as illustrated in FIG. 5) while also increasing the dose required for observed behavior of loss of solubility at high enough dose (such as illustrated in FIG. 6).

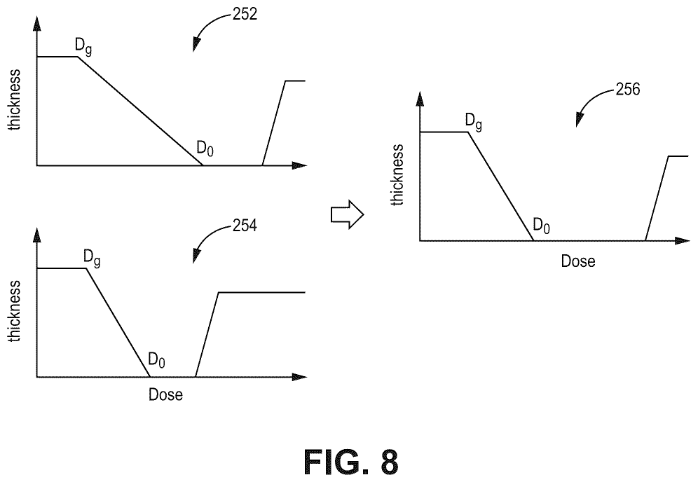

The DBDD process can show improved positive-tone patterning over a single PEB and single development process and over a double PEB and single development process, and can take advantage of the effects of both processes as depicted in FIG. 8. A single PEB and development (PEB1/Dev1) process (252) generally targets the dose of the high dose transition with an aqueous base developer, a dose that is generally desired to be as high as possible for optimal positive-tone processing. At low PEB temperatures, the dose of this high dose transition region can be increased. However, lower PEB temperatures also result in less radiolysis-induced thermolysis of the partially irradiated material which can generally lead to higher positive-tone D₀ values. A serial PEB process 254 of a first lower temperature PEB and a second higher temperature PEB with a single development (PEB1/PEB2/Dev1) can be used to drive more radiation-induced thermolysis in the partially irradiated material which can increase solubility of this material in aqueous base developer. However, the extent of condensation and densification in the fully irradiated areas also occurs which leads to greater insolubility in aqueous base developer, and an overall narrower positive-tone process window. By performing a DBDD process, the benefits of both single-development processes can be realized wherein the first lower temperature PEB and development process can remove a significant amount of irradiated material, and a second higher temperature PEB and development process can drive increased solubility of partially irradiated material.

With respect to the implications of the behavior seen in contrast curves on the practical effects of patterning features, if patterning is performed at a dose corresponding to the window of solubility in developer, the lower dose side of the process curve corresponds to physical placement near the pattern edge, so the wider process window may correspond with less residue at the pattern edge for a cleaner pattern. Suitable developers for positive tone development are weak aqueous acids or bases, such as tetramethyl ammonium hydroxide (TMAH), and the first developer and second developer can be the same or different.

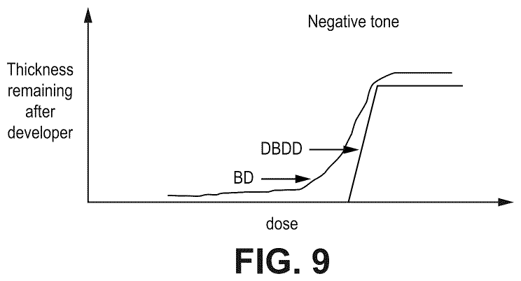

For negative tone development, there is no low dose side to the process curve, since the irradiation only serves to prevent removal of the material in development. The removed material is non-irradiated or irradiated at a dose insufficient to render the material insoluble. The second bake step again involves further condensation of the irradiated material. For negative tone development, the effects of the second bake-development steps are not related to a process window in the process curves, and the edge effects are related to the shape of the process curve as the dose increases. By limiting condensation, the process curve is more gradually sloped at lower doses. During the second bake, additional condensation takes place. The second developer for negative tone development generally can be more effective for hydrophilic material removal. So the second developer can be TMAH, a blend of an organic developer and an acid (such as heptanone and acetic acid), or the like. The second development step should be effective to modify the process curve to be more sharply rising. This is depicted in FIG. 9. The sharper process curve can result in less residue along the pattern edge when performing negative tone patterning with the DBDD process, as described herein.

For high volume semiconductor manufacturing it is generally desired for photoresists to be highly sensitive to radiation such that lower doses of energy are required to pattern features of a desired size. Continuing demands to improve efficiency and throughput generally require improvements to the entire semiconductor lithography ecosystem, not the least of which are demands on improving the sensitivity of the photoresist towards the exposure radiation. As the sensitivity of the photoresist increases, the number of photoreactions required to induce a solubility change in the photoresist decreases. Because the energy density of EUV photons is quite high compared to photons of ultraviolet or visible photons, the number of photons required to deliver a given dose is significantly lower than photons of longer wavelengths. In other words, it does not take as many EUV photons to generate a latent image pattern in the photoresist compared to photons of longer wavelengths, such as ultraviolet or visible photons. Therefore, as dose requirements for patterning photoresists decrease, it is desirable to mitigate the photochemical effects of the photons delivered to the unexposed regions of the pattern.

Organotin materials are particularly useful as organometallic photoresists for semiconductor lithography. Organotin photoresists have been broadly described in U.S. Pat. No. 9,310,684B2 to Meyers et al., entitled “Organometallic Solution Based High Resolution Patterning Compositions,” U.S. Patent Publication U.S. Pat. No. 10,642,153B2 to Meyers et al., entitled “Organometallic Solution Based High Resolution Patterning Compositions and Corresponding Methods,” and U.S. Patent Publication U.S. Pat. No. 10,228,618B2 (herein the '618 patent) entitled “Organotin Oxide Hydroxide Patterning Compositions, Precursors, and Patterning”, all of which are incorporated herein by reference. In general, these organotin photoresist materials are deposited as coatings in which Sn atoms are associated in an oxo-hydroxo network through Sn—OH and Sn—O—Sn bonds along with intact Sn—C bonds. The intact Sn—C bonds prevent extended dense network formation, and thus can maintain suitable solubility of the film in a developer. Exposure of organotin coatings to appropriate radiation sources, such as extreme ultraviolet (EUV), ultraviolet (UV), electron beams, and the like, results in cleavage of the Sn—C bond and allows for further densification of the exposed area, thereby increasing the solubility contrast between exposed and unexposed regions. In this way, patterning of the coating can be realized after development. The organotin photoresists are currently available commercially from Applicant Inpria Corporation.

The organotin resists can be useful for either negative tone patterning or positive tone patterning. The patterns formed with the organotin resists are not particularly limited, and can generally comprise complex layouts based on various mask patterns for device manufacturing. For testing of photoresist performance, masks comprising line/space and/or contact hole patterns can be particularly useful. In some embodiments, the patterns can be based on regularly spaced lines with patterned gaps between them (i.e., line/space patterns) or holes on a grid (i.e., contact hole patterns). The formation of holes on a grid is particularly suitable for positive tone patterning. For negative patterning of holes, the area surrounding the holes would be irradiated, in which case the holes would be subject to secondary electrons and shot noise from all sides, which makes the holes prone to having a lot of residue. As demonstrated below, positive tone patterning of holes can be performed effectively using the methods described herein.

The additives can be soluble in the solvent used to deliver the organotin patterning precursors to the substrate. As noted below, the solvent can be selected to achieve the suitable solubility of all of the relevant species. Processing can continue for deposition and irradiation. Following irradiation, the development can be adjusted as described above to take advantage of the presence of the additives. Overall, the processing with the additives can be effectively exploited for patterning that benefits from positive tone patterning, such as with hole formation, or if a double development approach is desirable to improve pattern quality.

### Precursor Solutions, Organotin Precursor Compositions and Additives

The additives are combined with precursors in a solvent to form precursor solutions for the organotin patterning compositions for delivery to a substrate. Solvents for the organotin precursors are generally suitable for dissolving the additives or can be selected accordingly. The additives are generally present in a mole ratio less than two relative to the tin atoms. As noted above, the additives can be a PAG, a quencher or a combination thereof.

The precursor solution generally comprises organometallic precursor compositions, additives and an organic solvent. The resist precursor composition can be conveniently specified based on tin ion molar concentration. In general, the resist precursor solution generally comprises from about 0.0025 M to about 1 M tin cation, in some embodiments from about 0.004M to about 0.9M, in further embodiments from about 0.005 M to about 0.75 M, also in some embodiments from about 0.01M to about 1M, and in additional embodiments from about 0.01 M to about 0.5 M tin cation. With respect to the additives, these can be specified as a mole ratio relative to the tin or as a molarity. The additive can be in the solution at a mole ratio to tin of 0.002 to 0.5, in further embodiment from about 0.0035 to about 0.45, in additional embodiments from about 0.005 to about 0.4 and in some embodiments from about 0.0075 to about 0.3 moles additive per mole of tin. Similarly, the precursor solution can comprise additive at a concentration from about 0.000025M to about 0.4M in further embodiments form about 0.00005M to about 0.35M and in additional embodiments from about 0.0001M to about 0.2M. A person of ordinary skill in the art will recognize that additional concentration ranges and values within the explicit ranges above are contemplated and are within the present disclosure.

Suitable organic solvents include, for example, alcohols or blends thereof. Generally, the solvents are at least 50 weight percent alcohols with any remaining organic solvent liquids being soluble in the alcohol, such as an alkane (such as pentane or hexane), an aromatic hydrocarbon (such as toluene), ether (such as diethyl ether, C₂H₅OC₂H₅), or mixtures thereof. As seen in the examples below, the solvent can be adjusted to confirm suitable solubility of the organotin precursors and any additives. In some embodiments, the solvent is at least 90 weight percent alcohol, and the solvent can be effectively alcohol with just trace impurities of other compounds. Suitable alcohols are generally monomeric alcohols with a melting point of no more than about 10° C., such as methanol, ethanol, propanol, butanol, pentanol, hexanol, heptanol, octanol, nonanol, decanol, branched versions thereof, and mixtures thereof. It has been found that controlling the water level can result in consistent and stable precursor solutions. In particular, the water level can be adjusted, generally by addition of small amounts of water to the solvent. to achieve the target water levels, generally no more than about 10,000 ppm by weight, and in additional embodiments from about 300 ppm by weight to about 2500 ppm by weight. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference.

The organotin compositions can be alkyl tin compositions that comprise a group of compositions (RSnL₃) that can be hydrolyzed with water or other suitable reagent under appropriate conditions to form the monohydrocarbyl tin oxo-hydroxo patterning compositions, which, when fully hydrolyzed, can be represented by the formula RSnO_{(1.5-(x/2))}(OH)ₓ where 0<x≤3. It can be convenient to perform the hydrolysis to form the oxo-hydroxo compositions in situ, such as during deposition and/or following initial coating formation. In particular, triamides and trialkoxides can be used under hydrolyzing conditions for forming radiation sensitive coatings for patterning, and current commercial products are based on trihydrocarbyloxides, such as trialkoxides. The various precursor compounds with hydrolysable ligands generally carry forward the R-ligand to tin through the process and are synthesized with this perspective. Hydrolysable ligands include, for example, alkoxide (hydrocarbyl oxide), acetylide, carboxylate, or amide moieties. These compositions can be synthesized with a wide range of R ligands, where R is a hydrocarbyl ligand with 1 to 31 carbon atoms with optional heteroatoms and/or optional unsaturated or aromatic functionality, while maintaining a carbon-tin bond. A range of synthesis approaches are available based on methods known in the art or developed by Applicant, and a particularly versatile approach which can provide good yields for a wide range of ligands is found in published U.S. patent application 2022/0064192 to Edson et al., entitled “Methods to Produce Organotin Compositions with Convenient Ligand Providing Reactants,” incorporated herein by reference.

For the organotin RSnL₃ compositions (or more generally RₙSnL₄₋ₙ, where 0.5<n<3), R forms a carbon-tin bond and can comprise heteroatoms, which are not carbon or hydrogen. As noted above, for convenience as well as consistency in the art, R can be interchangeably referred to as an alkyl ligand, organo ligand or hydrocarbyl ligand. In some embodiments, branched alkyl ligands can be desirable for some patterning compositions where the compound can be represented generally as R¹R²R³CSnO_{(2-(z/2)-(x/2))}(OH)ₓ, where R¹, R² and R³ are independently hydrogen or an alkyl group with 1-10 carbon atoms. Similarly, this representation of alkyl ligand R is similarly applicable to the other embodiments generally with R¹R²R³CSn(L)₃, with L corresponding to hydrolysable ligands, such as alkoxide (hydrocarbyl oxide), acetylide, carboxylate, or amide moieties. In some embodiments, R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CH₂CH₃), sec-butyl (R¹ is methyl, R² is —CH₂CH₃, and R³ is hydrogen), neopentyl (R¹ and R² are hydrogen, and R³ is —C(CH₃)₃), cyclohexyl, cyclopentyl, cyclobutyl, and cyclopropyl. Examples of suitable cyclic groups include, for example, 1-adamantyl (—C(CH₂)₃(CH)₃(CH₂)₃ or tricyclo(3.3.1.13,7) decane bonded to the metal at a tertiary carbon) and 2-adamantyl (—CH(CH)₂(CH₂)₄(CH)₂(CH₂) or tricyclo(3.3.1.13,7) decane bonded to the metal at a secondary carbon). In other embodiments, hydrocarbyl groups may include aryl or alkenyl groups, for example, benzyl or allyl, or alkynyl groups. In other embodiments, the hydrocarbyl ligand R may include any group consisting solely of C and H and containing 1-31 carbon atoms. In summary, some examples of suitable alkyl groups bonded to tin include, for example, linear or branched alkyl (i-Pr((CH₃)₂CH—), t-Bu((CH₃)₃C—), Me(CH₃—), n-Bu(CH₃CH₂CH₂CH₂—)), cyclo-alkyl (cyclo-propyl, cyclo-butyl, cyclo-pentyl), olefinic (alkenyl, aryl, allylic), or alkynyl groups, or combinations thereof. In further embodiments, suitable R groups may include hydrocarbyl groups substituted with hetero-atom functional groups including cyano, thio, silyl (and germanium analogs), ether, keto, ester, or halogenated groups or combinations thereof, such as one or more fluorine atoms and/or on or more iodine atoms. As is conventional in this art, the hydrocarbyl group can be referred to as an alkyl group even though the group can have unsaturated bonds, aryl groups, heteroatoms, and so forth.

As noted above, suitable additives can be a photoacid generator (PAG), quencher or a combination thereof. These compositions are generally ionic or zwitterionic. In some embodiments, a suitable PAG and quencher can be based on a common cation with the compositions differing by the nature of the anion. A PAG generally has an anion that is a conjugate base of a strong acid so that it is not significantly alkaline, while a quencher has an anion that is alkaline so that it neutralizes or buffers any protons released or otherwise present. As the name implies, quenchers can scavenge or neutralize acids to limit their spatial range. Generally, either compound can absorb secondary electrons or UV light with the generation of acid (PAG) or not (quencher). The generation of acids is found to facilitate removal of cleaved R groups from the patterning composition, and in any case removal of secondary electrons and limiting their range can be beneficial. The use of PAGs to absorb secondary electrons is described in published U.S. patent application 2018/0173096 to Zi et al., entitled “Extreme Ultraviolet Photolithography Method With Developer Composition,” incorporated herein by reference.

In some embodiments, the additive, electron-trapping agent, can be a compound capable of absorbing a photon or an electron (e.g., a secondary electron and/or a photoelectron) to produce a soluble reaction product. In some embodiments, the electron-trapping agent can be a compound capable of absorbing a photon or an electron to produce a product that can react with the organotin matrix to produce a soluble reaction product. Additives within the photoresist film can absorb photons and/or secondary electrons to yield photoproducts that do not significantly alter the radiolysis of the organotin materials within the irradiated regions of the photoresist during EUV patterning since the additives generally have weak absorption in the EUV. In the irradiated regions of the photoresist, many photons are absorbed to create a cascade of secondary electrons that can lead to decomposition of the tin-carbon bonds within the material. However, in the non-irradiated regions, the photons impacting the material are fewer in number and the secondary electrons generated can be significantly “quenched” by the presence of the additives, which can function as electron trapping agents, thereby reducing the number of tin-carbon bond cleavage events that would otherwise lead to insoluble products, i.e., defects. As noted above, absorption of electrons by additives may or may not result in acid release. As described above, the use of organotin photoresist compositions comprising an additive can modify the solubility profile of the photoresist such that the nominally non-irradiated dark regions of the pattern show increased solubility for negative tone developers while maintaining low solubility for positive tone developers. In other words, the number of photochemical events leading to insoluble species that occur from absorption of shot-noise photons or secondary electrons can be reduced in organotin photoresist compositions comprising additives as electron-trapping agents.

While not wanting to be limited by theory, the additives are thought to act similar to a competitive inhibitor or quencher with respect to the photoreactions of the organotin matrix, especially with respect to reactions that occur in the non-irradiated regions due to stray radiation. It is generally believed that as photons are absorbed by the photoresist film composition, radiolysis occurs and ionization products are produced wherein secondary electrons (i.e., photoelectrons) are generated in the photoresist film. These secondary electrons can then migrate through the film to drive further ionization events. These secondary electrons are capable of driving photochemical reactions within the organotin photoresist film, such as dealkylation of organotin species (e.g., R—Sn bonds). While dealkylation is generally desirable for nominally irradiated regions of the photoresist, it is generally undesired for dealkylation to occur in the non-irradiated regions of the photoresist. Therefore, the additive compositions described herein can be used to mitigate undesired dealkylation events in the non-irradiated regions of the photoresist. In this way, the additive compositions can improve the performance of organotin photoresists.

As noted above, additives can be photoacid generators (PAGs), quenchers or mixtures thereof. PAGs produce acids in response to adsorption of light and/or heat and are known in the photolithography art. While PAGs can generally absorb at UV and EUV wavelengths, their presence in an already high EUV absorbance Sn-based matrix implies that the presence of PAGs does not significantly attenuate EUV light available to the organotin patterning compositions. PAGs can also generate acidic protons in response to secondary electrons generated from EUV absorption. Evidence herein suggests that PAGs facilitate removal of organic species from irradiated patterning composition, which are presumed related to the cleaved R-groups freed from their bond to the tin.

PAGs generally have an anion and a cation or can be zwitterionic. PAGs known in the art are generally onium compounds, which have a cation formed from a group 15 to group 17 core atom, such as iodonium, sulfonium, ammonium, phosphonium, and the like. Particularly effective PAGs have aromatic substituents and derivatives thereof.

The anion counterion for a PAG is generally a conjugate base to a strong acid so that the anion does not neutralize a released acid from the cation. However, to maintain solubility in an organic solvent, the anion should be appropriately selected. Various anions are thus popular in the art based on appropriate solubility and availability. Specifically, aromatic sulphonates are effective anions. Suitable anions generally include, for example, naphthalene-1-sulfonate, naphthalene-2-sulfonate, 2-t-butyl-naphthalene-2-sulfonate and the like; anthracene derivatives such as anthracene-1-sulfonate, anthracene-2-sulfonate, 9-nitroanthracene-1-sulfonate, 5,6-dichloroanthracene-3-sulfonate, 9,10-dichloroanthracene-2-sulfonate, 9,10-dimethoxy anthracene-2-sulfonate, 9,10-diethoxy anthracene-2-sulfonate, benz (a) anthracene-4-sulfonate and the like; anions having other type of polycyclic structures such as phenanthrene-2-sulfonate, pyrene-sulfonate, tripheny lene-2-sulfonate, chrysene-2-sulfonate, anthraquinone-sulfonate and the like; trifluoromethane sulfonate; hexafluoro antimonate; tetrafluoroborate; hexafluoro phosphate; benzene sulfonate and the like.

Desirable quenchers can have the same cations as the PAGs to provide secondary electron reaction but have anions that are alkaline so that they neutralize or buffer acidic protons. The anion can be a hydroxide to neutralize the acidic proton or a weaker base that can still be effective for binding acidic hydrogens, such as carbonates or sulfates.

Onium salt based quenchers are described in published U.S. patent application 2023/0161254 to Fukushima et al. (hereinafter '254 application), entitled “Chemically Amplified Resist Composition and Patterning Process,” incorporated herein by reference. The '254 application teaches a range of onium cations, but lists specific aromatic species, which are desirable from a solubility perspective and from a quenching perspective with respect to secondary electrons, but aromatics with smaller steric volumes can be desirable to avoid excessive inhibition of condensation of irradiated material. The '254 application refers to RCO₂⁻ as anions, where R is a hydrocarbyl groups with possible heteroatom substitution. The R for these anions can be H or a hydrocarbyl group with 1 to 40 carbon atoms and optional heteroatoms. The R group can be selected for desired solubility properties and process convenience and may comprise aromatic groups. The PAG anions can comprise sulfonate or phosphonate groups with organic functional groups, which can comprise from 1 to 40 carbon atoms with optional heteroatoms. For the quencher and/or PAG anions, it can be desirable to have aromatic groups for solubility.

As noted above, onium ions are analogs to ammonium and can have core atoms from various groups in the periodic table. Onium ions of particular interest have core atoms from group 15 (N, P, As, Sb or Bi), group 16 (O, S, Se, Te or Po) or group 17 (I, F, Cl or Br), although ions are known for boron, group 14 atoms and noble gases. The onium ions generally have structures represented by ARₙ⁺, where “A” represents the core atom of the ion, R represents ligands off of A, and n is the number of ligands. R is generally a hydrocarbyl group with 1 to 20 carbon atoms and with optional heteroatoms. It can be desirable for R to comprise aromatic groups, such as benzyl groups, and fluorine or other halogen substitutions can be desirable, such as fluorobenzyl groups. Sulfonium ions and iodonium ions are exemplified herein. Some specific species follow.

Some suitable examples of quenchers are organoiodonium hydroxides, such as diphenyl iodonium hydroxide and bis(3-tert-butylphenyl) iodonium hydroxide, and organosulfonium hydroxide compounds, such as triphenyl sulfonium hydroxide, tris(4-fluorophenyl) sulfonium hydroxide, and diphenyl(4-cyclohexylphenyl) sulfonium hydroxide, and the like.

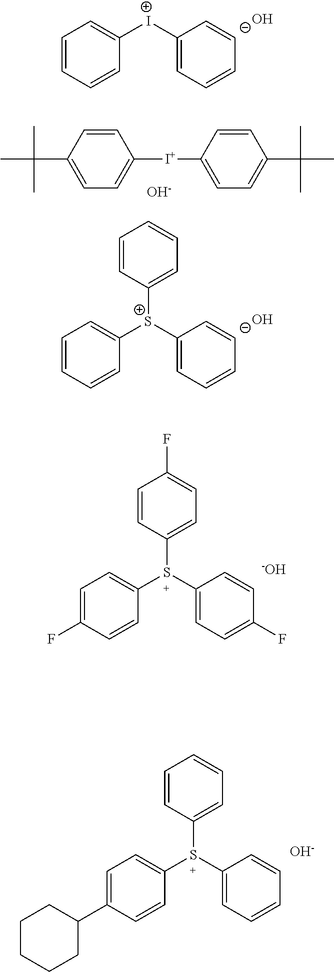

When the electron-trapping agents are included in the organotin compositions, the agents can capture electrons to mitigate undesired Sn—C bond cleavage in the non-irradiated regions of photoresist film to result in soluble products, as illustrated by the following reaction scheme:

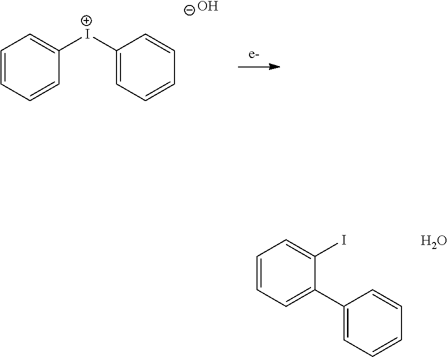

In some embodiments, the electron-trapping agent can be first dissolved in a solvent that is different than the solvent comprising the organotin photoresist solution and then later combined with the organotin photoresist solution to form the additive-modified organotin photoresist solution. In general, it is desirable for the electron-trapping agent additive to be dissolved in a solvent that is conducive to processing of the resulting additive-modified organotin photoresist solution.

Photoelectron absorbents for organic photoresists, including chemically amplified photoresists, have been described in U.S. Publication No. 2009/0317742 by Toriumi et al., which is incorporated herein by reference. The photoelectron absorbent described by Toriumi et al. is described as being suitable for photosensitive resin compounds mainly composed of hydrogen, carbon, and oxygen. Toriumi et al. does not contemplate organotin photoresist compositions nor the problem of off-target tin-carbon bond cleavage. Generally, compounds free of metal are desired for use herein to avoid metal contamination. Also, the hydroxide anions are desired to avoid forming photoacid generators.

After formation of the organotin photoresist solutions comprising an electron-trapping agent, the solutions can be further processed, such as by performing filtration, to suitably prepare the solutions for use. Filtration can be effective at removing inhomogeneities, such as undesired particles, from organotin resist solutions, and such methods have been described by Clark et al. in published U.S. Patent App. No 2020/0239498, entitled “Monoalkyl Tin Trialkoxides And/Or Monoalkyl Tin Triamides With Particulate Contamination And Corresponding Methods”, incorporated herein by reference.

### Patterning of the Compositions

As noted above, the photoresist precursor solutions with organotin compositions and additives (additive enhanced photoresist precursor solution) can be used to form radiation-patternable organotin oxo hydroxo materials incorporating the additives, and such coatings can be formed using any suitable method known in the art. Spin coating can be particularly desirable for forming coatings using the additive-enhanced photoresist precursor solutions. In a typical spin coating process, a volume of an additive-enhanced photoresist solution is introduced onto the surface of a substrate, and the substrate is rotated at high speeds to drive rapid evaporation and hydrolysis processes to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. A person or ordinary skill in the art will recognize that additional ranges of spin coating parameters within the explicit ranges above are contemplated and are within the present disclosure.

A substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. Some substrates of interest include, for example, silicon wafers, silica substrates, other inorganic materials, polymer substrates, such as organic polymers, composites thereof and combinations thereof across a surface and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, viscosity and the spin speed for spin coating. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1 centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate to densify the coating material, to speed the processing, to increase the reproducibility of the process, and/or to facilitate vaporization of the hydrolysis by-products, such as alcohols and/or amines. In embodiments in which heating of the coated substrate is performed prior to irradiation, the coated substrate can be heated to temperatures from about 45° C. to about 250° C., and in further embodiments from about 55° C. to about 225° C. The heating can generally be performed for at least about 0.1 minute, in further embodiments for about 0.5 minutes to about 30 minutes, and in additional embodiments from about 0.75 minutes to about 10 minutes. A person of ordinary skill in the art will recognize that additional ranges of heating temperatures and times within the explicit ranges above are contemplated and are within the present disclosure.

Generally, photoresist coatings can be patterned using radiation. Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. The efficacy of the additives can be especially pronounced using EUV radiation since the additives generally do not strongly absorb radiation in the EUV so the additives do not reduce effective light intensity for the organotin material. Radiation can generally be directed to the substrate material through a mask or a radiation beam can be controllably scanned across the substrate to form a latent image within the resist coating. As noted above, for EUV “masking” the patterns are formed using mirrors to reflect and direct light from a plasma source.

Following International Standard ISO 21348 (2007) incorporated herein by reference, ultraviolet light extends between wavelengths of greater than or equal 100 nm and less than 400 nm. A krypton fluoride laser can be used as a source for 248 nm ultraviolet light. The ultraviolet range can be subdivided in several ways under accepted Standards, such as extreme ultraviolet (EUV) from greater than or equal 10 nm to less than 121 nm and far ultraviolet (FUV) from greater than or equal to 122 nm to less than 200 nm. A 193 nm line from an argon fluoride laser can be used as a radiation source in the FUV. EUV light has been used for lithography at 13.5 nm, and this light is generated from a Xe or Sn plasma source excited using high energy lasers or discharge pulses. Commercial sources of EUV photons include scanners fabricated by ASML Holding N.V. Netherlands. Soft x-rays can be defined from greater than or equal 0.1 nm to less than 10 nm.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² and in further embodiments from about 3 mJ/cm² to about 50 mJ/cm². A person of ordinary skill in the art will recognize that additional ranges of radiation fluences within the explicit ranges above are contemplated and are within the present disclosure.

Following exposure to radiation and the formation of a latent image, a subsequent postexposure bake (PEB) is typically performed. In some embodiments, the PEB can be performed at temperatures from about 45° C. to about 250° C., in additional embodiments from about 50° C. to about 190° C. and in further embodiments from about 90° C. to about 185° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure. The PEB can be designed to further consolidate the exposed regions without decomposing the un-exposed regions into a metal oxide.

Applicant has found that the PEB can contribute significantly to radiation induced thermolysis. In other words, the irradiated structures can initially undergo radiolysis so that irradiation induces cleavage of the hydrocarbyl ligands and removal of the material of product species formed form the cleaved ligands. But a PEB is found to further result in loss of additional organic moieties from the irradiated material, which can be termed radiation induced thermolysis since neither processing separately results in the same degree of loss of organic species from the material. The loss of organics from the material can be measured using infrared spectroscopy tuned to organic frequencies, as described further in the Examples. It has been found that PAGs improve the efficacy of radiolysis induced thermolysis. Furthermore, it is found that increasing the PEB temperature above 160° C. also improves the radiolysis induced thermolysis. PEB temperatures also are controlled to achieve desirable results from procedures with bake-develop-bake-develop (double bake-double develop or DBDD) protocols, as described further below.

Following performing a PEB, development of the image involves the contact of the patterned coating material including the latent image to a developer composition to remove either the un-irradiated coating material to form the negative image or the irradiated coating to form the positive image. Irradiated regions of organotin oxide hydroxide coatings are generally hydrophilic and are thus soluble in aqueous bases and insoluble in organic solvents; conversely, non-irradiated regions are generally hydrophobic and are thus soluble in organic solvents and insoluble in aqueous bases. For negative tone imaging, the developer can be an organic solvent, such as the solvents used to form the precursor solutions.

Specifically, for positive tone imaging, suitable developers generally can be aqueous bases. In some embodiments, aqueous bases can be used to obtain sharper images. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent. Furthermore, mixed quaternary tetraalkyl-ammonium hydroxides can be used. In general, the developer can comprise from about 0.5 to about 30 weight percent, in further embodiments from about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure. For a positive tone developer, it can be desirable to dissolve material densified from a relatively high radiation dose, assuming that the non-irradiated material is not significantly removed. This opens up the process window further.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. Improved developer compositions have been described in published U.S. Patent Application No.: 2020/0326627 to Jiang et al., entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid. The development can be performed for about 5 seconds to about 30 minutes, in further embodiments from about 8 seconds to about 15 minutes and in addition embodiments from about 10 seconds to about 10 minutes. A person of ordinary skill in the art will recognize that additional ranges within the explicit ranges above are contemplated and are within the present disclosure.

For negative tone development, developer selection can be effectively influenced by solubility parameters with respect to the coating material, both irradiated and non-irradiated, as well as developer volatility, flammability, toxicity, viscosity and potential chemical interactions with other process material. Some useful developer compositions for these organotin oxide photoresists have been described in published U.S. Patent Application No. 2020/0326627 to Jiang et al., entitled “Organometallic Photoresist Developer Compositions and Processing Methods”, incorporated herein by reference. In particular, developers can have differing amounts of more polar or less polar components, which can be specified more specifically with solubility parameters. In some embodiments, the solvent blend can comprise at least two solvents with at least 55 volume % of one or more solvents each independently having a sum of Hansen solubility parameter δH+δP of no more than about 16 (J/cm³)^{1/2}, and with from about 0.25 volume % to about 45 volume % of one or more solvents each independently having a sum of Hansen solubility parameter δH+δP of at least about 16 (J/cm³)^{1/2}. As noted below, for double bake-double develop processing, the second development can involve a developed for a negative tone pattern can comprise all or a larger percentage of a solvent having a sum of Hansen solubility parameter δH+δP of at least about 16 (J/cm³)^{1/2}, or a positive tone developer can be used in the second step of a negative tone patterning.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant that facilitates removal of irradiated or non-irradiated regions. Following development, a rinse step can be conducted if desired to further remove undesired material from the pattern, and such methods have been described in published U.S. Patent Application No. 2020/0124970 to Kocsis et al., entitled “Patterned Organometallic Photoresists and Methods of Patterning,” incorporated herein by reference. In the context of DBDD, dry development may be used for one (first or second) development step or both development steps.

The potential effects of the additives with respect to solubilities are described above. These effects can be further exploited using a DBDD process for either a negative tone patterning or positive tone patterning. In the context of positive-tone patterning, during the first development step, at least a significant portion of the irradiated additive-containing material can be removed by a developer. The second bake step can be performed at a higher temperature to facilitate further dealkylation in partially irradiated regions, increasing that material's polarity and, thus, solubility in the developer used in a second development step.

As noted above, additives can be photoacid generators (PAGs), quenchers or mixtures thereof. PAGs produce acids in response to adsorption of light and are known in the photolithography art. While PAGs can generally absorb at UV and EUV wavelengths, their presence in an already high EUV absorbance Sn-based matrix implies that the presence of PAGs does not significantly attenuate EUV light available to the organotin patterning compositions. PAGs can also generate acidic protons in response to secondary electrons generated from EUV absorption. Evidence herein suggests that released acidic protons facilitate removal of organic species from irradiated patterning composition, which are presumed related to the cleaved R-groups freed from their bond to the tin. On the other hand, quenchers neutralize acidic protons. Quenchers may also release acidic protons, but these can be effectively neutralized by quencher alkaline anions.

After completion of the development step including any optional rinses, the coating materials can be heat treated to further condense the material and to further dehydrate, densify, or remove residual developer from the material. This heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, nonthermal treatments, including blanket UV exposure, or exposure to an oxidizing plasma such as O₂ may also be employed for similar purposes.

In the context of DBDD, the PEB is in some sense broken up into two process steps: a first bake step and a second bake step after a first development. In a DBDD context, a first PEB can be performed at temperatures from about 45° C. to about 200° C., in additional embodiments from about 60° C. to about 175° C. and in further embodiments from about 85° C. to about 150° C. A second PEB after a first development can be performed at temperatures from about 145° C. to about 250° C., in further embodiments form about 150° C. to about 225° C., and in other embodiments from about 160° C. to about 200° C. In addition, the second PEB step generally is performed at least about 5° C. above the first PEB temperature, in further embodiments from about 10° C. to about 100° C. above the first PEB temperature, and in some embodiments from about 15° C. to about 85° C. above the first PEB temperature. PEB temperatures should be selected low enough to avoid thermolysis independent of irradiation since contrast can be lost. Generally, either post-exposure heating can independently be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure. Additional bake-development cycles can be included, if desired.

To further improve the positive tone patterning performance of the compositions described herein, a double bake double development (DBDD) process can be used. In such a DBDD process, a first PEB is performed after EUV irradiation to stabilize and lightly densify the material. Following the first PEB, a first development with aqueous base can be performed to remove the irradiated material. The first PEB can drive formation of high polarity and low density dealkylated Sn species within the irradiated regions of the film and improving removal of the material in such regions in an aqueous base developer. Next, a second bake can be performed at the same or higher temperature than the first PEB followed by a second development with an aqueous base. The second bake can drive further radiolysis induced thermolysis (i.e., dealkylation) of lightly exposed material, such as material near feature edges receiving intermediate dose, to form more polar but lightly condensed Sn species that can be better removed during a second development with an aqueous base.

The DBDD process can allow for initial removal of irradiated material having high solubility in aqueous developer. During EUV exposure and an initial PEB, Sn—C bonds are broken and the associated organic groups are liberated (i.e., dealkylation) from the film which drives a polarity change in the material. Initially the organotin material is relatively non-polar and hydrophobic due to the presence of the organic groups within the film. After EUV exposure, an initial bake, and liberation of the organic groups, the irradiated material is converted to a higher polarity hydrophilic material. In intermediate dose regions, such as near feature edges where the radiation aerial image is blurred, incomplete dealkylation and/or condensation can occur to yield partially soluble species. A second PEB can therefore be desirable to further dealkylate the material in the partially soluble regions and increase their polarity, thereby increasing the solubility in an aqueous base in a second development step. In other words, the second PEB and second development can improve the positive tone contrast of the pattern. The second developer can be the same or different positive tone developer relative to the first positive tone developer. As noted above, positive tone developers are generally aqueous alkaline (base) solutions.

For negative tone patterning, the first development removes nonirradiated material. The second bake step at a higher temperature promotes further condensation via radiolysis-induced thermolysis of the non-solubilized but partially irradiated material to form a partially condensed soluble material. As a result, a second development step can be performed using a developer comprising an acid or base. Suitable second acidic developers can comprise aqueous or organic solvents. Developers with organic solvents and organic acids, such as acetic acid, formic acid or other carboxylic acids are described in the '627 application cited above. Aqueous developers with acids or bases generally encompass positive tone developers, such as TMAH, which does not strip the patterning material due to the high consolidation of the irradiated material following the second bake step. An expected sharpening of the pattern edges is reflected in FIG. 9, which is further described above. For negative development using DBDD, the second developer is generally different from the first developer and can comprises an acid or base, in a Bronsted sense in an aqueous or non-aqueous solvent.

EUV lithography is generally used for very small resolution features to take advantage of the small wavelength of the light. Patterning for device formation generally is leveraged from an initial pattern that can be effectively formed on the substrate. The pattern can comprise a variety of features, for example, stripes, posts or holes. While negative tone patterning has so far proven most effective for very small, high resolution stripes (i.e., line/space patterns) using organotin resists, negative tone patterning of holes is more challenging. In particular, for negative tone patterning of holes, the area around the holes is necessarily irradiated such that the hole is surrounded by irradiated material. Therefore, the material within the hole can suffer from exposure to shot-noise photons and/or secondary electrons emitted from the irradiated material encircling the hole, so residue in the hole after negative-tone development can be problematic. With the improved positive tone imaging as disclosed herein using organotin patterning material, holes can be effectively patterned with low residue, as disclosed in the examples below.

In some embodiments involving stripes, adjacent linear segments of neighboring structures can have an average pitch (half-pitch) of no more than about 60 nm (30 nm half-pitch), in some embodiments no more than about 50 nm (25 nm half-pitch) and in further embodiments no more than about 34 nm (17 nm half-pitch). Pitch can be evaluated by design and confirmed with scanning electron microscopy (SEM), such as with a top-down image. Patterns can be evaluated, for example, with a Hitachi CG5000 CD-SEM instrument, or the like. As used herein, pitch refers to the spatial period, or the center-to-center distances of repeating structural elements, and as generally used in the art a half-pitch is a half of the pitch. Feature dimensions of a pattern can also be described with respect to the average width of the feature, which is generally evaluated away from corners or the like. The line widths are also referred to as a critical dimension (CD), and the critical dimension can be used to evaluate available feature sizes for a particular dose. For holes on a grid, a corresponding critical dimension is the hole diameter. Also, features can refer to gaps between material elements and/or to material elements. In some embodiments, average widths can be no more than about 25 nm, in further embodiments no more than about 20 nm, and in additional embodiments no more than about 15 nm. A person of ordinary skill in the art will recognize that additional ranges of pitch and average widths within the explicit ranges above are contemplated and are within the present disclosure. Based on these processes, the patterning can be adapted to the formation of various devices such as electronic integrated circuits, generally through the repeated patterning process to form appropriately layered structures, such as transistors or other components.

Wafer throughput is a substantially limiting factor for implementation of EUV lithography in high-volume semiconductor manufacturing, and is directly related to the dose required to pattern a given feature. However, while chemical strategies exist to reduce imaging dose, a negative correlation between the imaging dose required to print a target feature, and feature size uniformity (such as LWR) is commonly observed for EUV photoresists at feature sizes and pitches<50 nm, thereby limiting final device operability and wafer yields. Photoresist sensitivity can be expressed in terms of the dose-to-gel value, and imaging dose requirements can be evaluated by forming an array of exposed pads in which the exposure time is stepped from pad to pad to change the dosing of the exposure. The film can then be developed, and the thickness of the remaining resist can be evaluated for all of the pads, for example, using spectroscopic ellipsometry. The measured thicknesses can be normalized to the maximum measured resist thickness and plotted versus the logarithm of exposure dose to form characteristic contrast curves. The maximum slope of the normalized thickness vs log dose curve is defined as the photoresist contrast (γ), and the dose value at which a tangent line drawn through this point equals 1 is defined as the photoresist dose-to-gel, (D_{g}). For positive tone development, the contrast curve typically shows a decrease in thickness after development with increasing dose. However, as the dose is further increased the oxide hydroxide network further condenses and becomes insoluble and the thickness after development increases. So with positive tone patterning of organotin photoresist compositions, there are two transition regions with the first dropping in thickness and the second increasing in thickness. Each transition region can be characterized by values of γ and D_{g}, where the slopes change sign relative to each other. Thus, the terms can be defined comparably for the two parts of the curve. In this way common parameters used for photoresist characterization may be approximated following Mack, C. Fundamental Principles of Optical Lithography, John Wiley & Sons, Chichester, U.K; pp 271-272, 2007. EUV image analysis is described further in P. De Bisschop and E. Hendrickx “Stochastic effects in EUV lithography”, Proc. SPIE 10583, Extreme Ultraviolet (EUV) Lithography IX, 105831K (19 Mar. 2018); https://doi.org/10.1117/12.2300541, incorporated herein by reference.

### EXAMPLES

### General Photoresist Preparation

All photoresist solutions described in the following examples were prepared by dissolving and mixing appropriate masses of tBuSn(OtAm)₃ precursor and MeSn(OtAm)₃ precursor in a solvent system as described in Table 1 to achieve a molar ratio of 80% tBuSn:20% MeSn for all photoresist solutions. Prior to the addition of the organotin precursors, the solvent systems were additionally mixed with a water source to contain about 300 ppm water using the methods described in the '876 patent. Appropriate masses of the additives described in Table 2 were then added and thoroughly mixed to form photoresist solutions having a concentration of approximately 0.04 M Sn.

TABLE 1

| Solvent System | Composition |
|---|---|
| S1 | 4-methyl-2-pentanol |
| S2 | 55% by vol. 4-methyl-2-pentanol + 45% by |
| | vol. 1-propanol |

TABLE 2

| Additive | | |
|---|---|---|
| Reference | | MW |
| Name | Additive Formula | (g/mol) |
| A1 | | 542.7 |
| A2 | 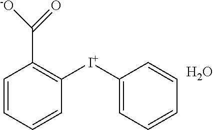 | 342.1 |
| A3 | 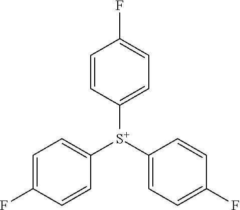 [SMILES: Fc1ccc([S+](c2ccc(F)cc2)c2ccc(F)cc2)cc1] | 522.5 |
| | 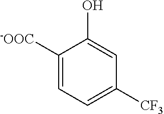 | |
| A4 | 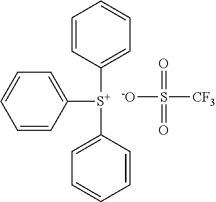 | 412.5 |

Additive-enhanced solution compositions were prepared by adding appropriate masses of each additive to form precursor coating samples having desired molar ratios of additive to Sn (A:Sn) of 0.01, 0.02, and 0.05 (i.e., 1%, 2%, and 5%, respectively, by mole), and the target concentrations are summarized in Table 3 below:

TABLE 3

| Precursor | | | Molar Ratio |
|---|---|---|---|
| Coating Sample | Solvent System | Additive | (additive:Sn) |
| C (control) | S1 | none | n/a |
| 1 | S2 | A1 | 0.01 |
| 2 | S2 | A1 | 0.02 |
| 3 | S2 | A1 | 0.05 |
| 4 | S2 | A2 | 0.01 |
| 5 | S2 | A2 | 0.02 |
| 6 | S2 | A2 | 0.05 |
| 6b | S2 | A2 | 0.04 |
| 7 | S2 | A3 | 0.01 |
| 8 | S2 | A3 | 0.02 |
| 9 | S2 | A3 | 0.05 |
| 9b | S2 | A3 | 0.035 |
| 10 | S2 | A4 | 0.05 |
| 11 | S2 | A4 | 0.1 |

### General Coating and Processing

Silicon wafers having a ˜10 nm layer of spin-on-glass (SOG) were used as substrates. Spin-coating was used to deposit each photoresist sample to yield photoresist films of approximately 20 nm thickness. Following deposition, the wafers were subjected to a post-apply bake (PAB) on a hot plate at various temperatures prior to EUV exposure.

For preparation of contrast curves, exposure to patterned EUV radiation was conducted on an ASML NXE3400C EUV Scanner operating in an open frame (i.e., no patterning within a pad) to produce an array of pads exposed at different dose. The exposed wafers were then subject to a post-exposure bake (PEB) at a selected temperature from 100° C. to 200° C. The exposed films were then developed with 2.38% by weight TMAH (aq) solvent for 30 seconds to develop the latent image into a positive tone pattern, i.e., the developer solvent was used to remove exposed portions of the coating. Films were then rinsed with H₂O and spun dry and a final 1-min hotplate bake at 250° C. in air was performed after development to densify the pattern. The residual thickness of each exposed pad was measured via ellipsometry and the values are plotted versus the logarithm of exposure dose to form characteristic contrast curves for each film sample.

### Example 1: Additive A1 Films, Patterning, and Contrast Curves

This example presents contrast curves for organotin oxide hydroxide photoresist compositions and shows the effect of incorporating a PAG additive (A1) as well as the effects of the concentration of the PAG additive and the post-exposure bake (PEB) temperature on the processing window for positive tone development of the photoresist compositions.

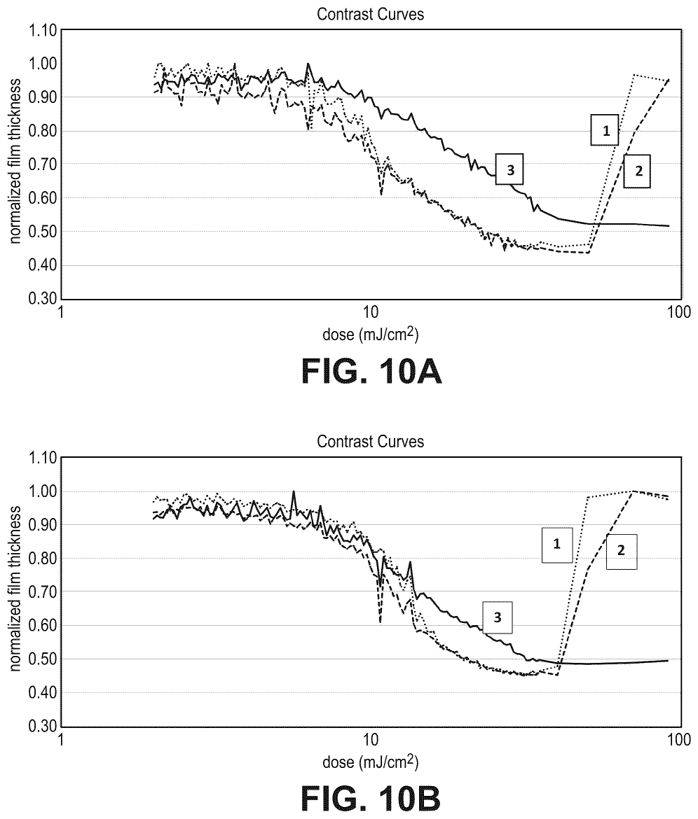

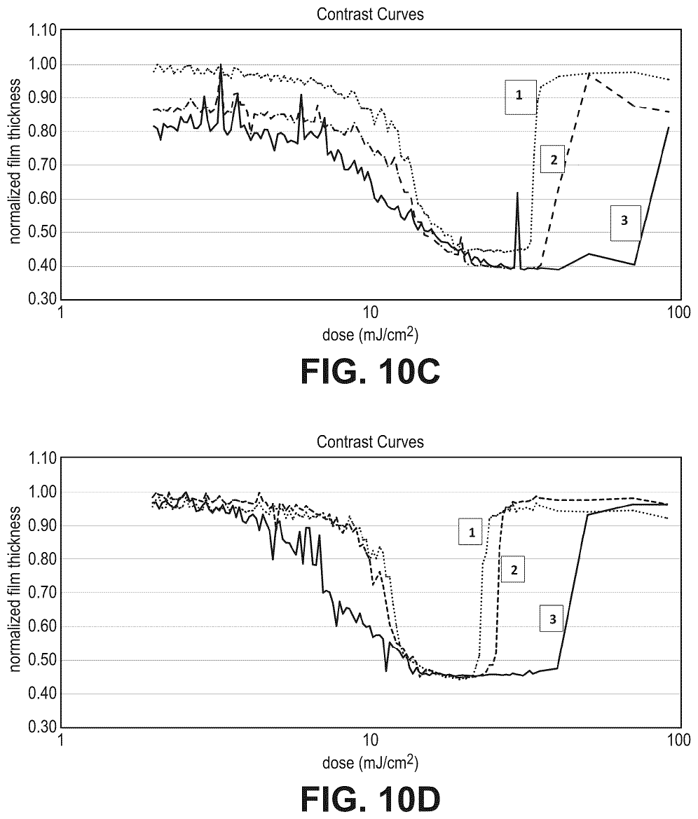

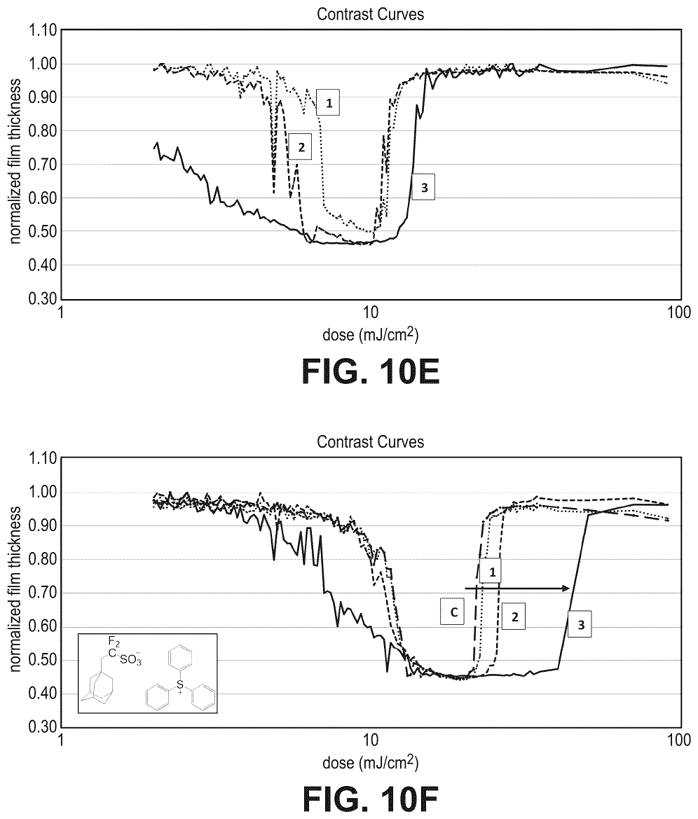

A series of photoresist films (1, 2, 3, and C) were prepared from precursor coating samples 1, 2, 3, and C, respectively. Following deposition, the films were subjected to a PAB of 100° C. for 60 s. Following EUV exposure, each of films 1, 2, and 3 was subjected to a 60 s PEB at 120° C., 140° C., 160° C., 180° C., or 200° C. Film C was subjected to a 60 s PEB at 180° C. Contrast curves were produced for each sample according to the methods described above and plotted in FIGS. 10A-10F.

FIGS. 10A through 10E show contrast curves at PEB temperatures 120° C., 140° C., 160° C., 180° C., and 200° C., respectively, for additive-containing films prepared from samples 1, 2, and 3. Considering the results for each of the PEB temperatures, it can be seen that the width of the low film thickness region of the contrast curves generally increases with increasing concentration of the additive A1. This indicates an increase in the solubility of the exposed film and a broadening of the processing window for positive tone patterning. In general, the presence of the additive increases the positive-tone process window by pushing the negative-tone transition region to a higher dose and pushing the positive-tone transition region to a lower dose.

FIG. 10F shows a contrast curve for film samples 1, 2, and 3 alongside the non-additive containing control sample C, with all of the film samples represented in FIG. 10F having been subjected to a PEB of 180° C. A broadening of the processing window was observed with increasing molar ratio of the additive (PAG:Sn) from 0 to 0.05. The arrow in FIG. 10F indicates increasing additive concentration. As explained in the detailed description above and illustrated in FIG. 7, this example shows that the presence of the A1 additive at even the lowest concentration ratio provided an increase in the upper range of the dose for which the exposed resist could be removed. This increase in the upper range of the dose was most pronounced for film sample 3, the sample with the highest molar ratio of the PAG additive. Considering the lower range of the dose for which the exposed resist could be removed, a concentration effect of the additive is also evident yet less pronounced than at the higher range of the dose.

This study shows a clear positive correlation between increasing PAG additive concentration in an organometallic photoresist composition and the widening of the positive tone processing window. This study also shows that the processing window for the A1 additive-containing compositions could be tailored by adjusting PEB temperature.

### Example 2: Additive A4 Films, Patterning, Contrast Curves, and Radiolysis-Induced Thermolysis Improvement

This example shows the effects of post-exposure bake conditions on the processing window for positive tone development of organometallic photoresist compositions incorporating PAG additive A4.

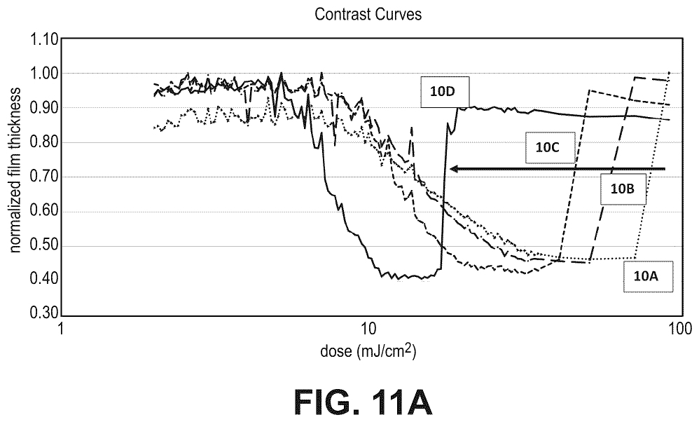

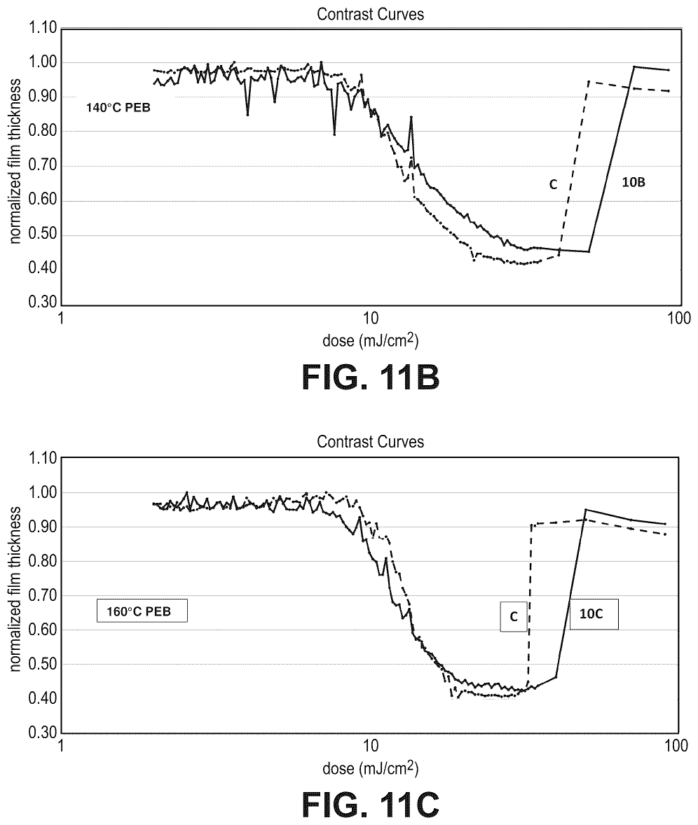

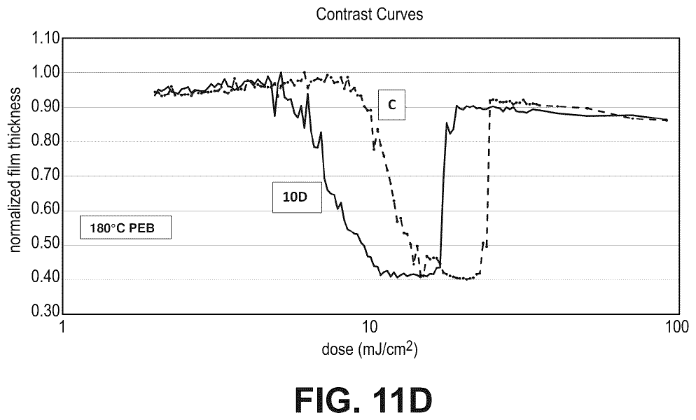

A series of photoresist films were prepared from precursor coating sample 10. Following deposition, the films were subjected to a PAB of 100° C. for 60 s. Following EUV exposure, each film was subjected to a 60 s PEB at 120° C. (Sample 10A), 140° C. (Sample 10B), 160° C. (Sample 10C), or 180° C. (Sample 10D). A control film C was prepared from precursor coating sample C as described above and subjected to a PEB at 180° C. Contrast curves were produced for Samples 10A-10D according to the methods described above and plotted in FIG. 11A.

FIG. 11A shows contrast curves corresponding to Samples 10A-10D. The arrow in FIG. 11A points in the direction of increasing PEB temperature for the samples. FIG. 11A shows that the PEB temperature had generally expected effects on the high dose rise of the curve corresponding to the dose-to-gel, the D₀, and the contrast of the films. The PAG additive-containing films also showed other PEB temperature effects. In particular, as the PEB temperature increases, the dose associated with the transition of the exposed material from soluble to insoluble (right hand side of the contrast curve) decreases. The transition from soluble material to insoluble material is believed to be related to the condensation of the exposed material at a given dose. After the transition, the condensation of the exposed material inhibits removal with the positive tone developer. The contrast curves for Samples 10A-10D show that an increase in PEB temperature lowers the upper dose range of the solubility window, but also lowers the lower dose range of the solubility window. The broadening of the lower dose range of solubility with increasing PEB temperature is believed to be related to radiolysis induced thermolysis, as discussed below. At a PEB of 180° C. (Sample 10D) both edges of the contrast curves shift to significantly lower doses. FIG. 11A also shows that the PEB temperature affects the field thickness of the exposed film, with higher PEB temperatures reducing the loss of film thickness (“top loss”) in the lower dose regions.

FIGS. 11B-11D compare the contrast curves for Samples 10B-10D, respectively, with control film C. The comparisons in each of FIGS. 11B-11D show that below a PEB temperature of 180° C., the A4 additive increases the process window (dose range for the lower part of the contrast curve) on the higher dose side of the contrast curves. This suggests that the additive is functioning as a condensation inhibitor. Referring to FIG. 11D, at a PEB temperature of 180° C., it is observed that the presence of the additive A4 shifts the entire curve to lower doses. Importantly, the low-dose side transition region of the contrast curve is shifted to a lower dose while exhibiting a similar contrast as the non-additive composition C. These effects of the additive allow for high contrast, positive-tone processing at lower doses than the control.

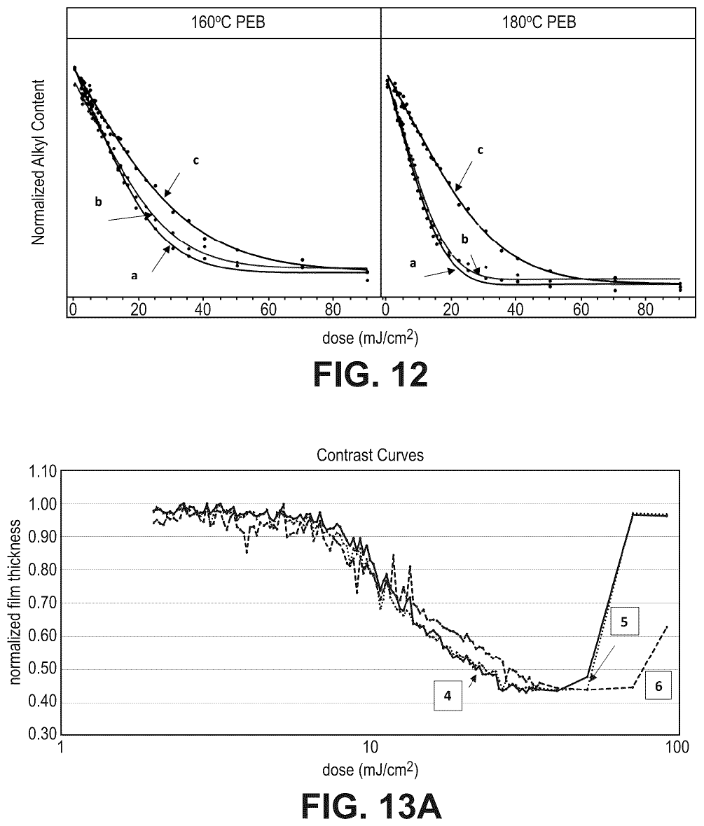

To understand the effect of additive A4 on the patterning behavior of the resist composition, Fourier transform infrared (FTIR) spectroscopy was employed to analyze the C—H absorption of the films as a function of EUV dose and PEB. Resist precursor coating samples 10, 11, and C were individually spin-coated onto silicon wafers at conditions to yield approximately 20 nm thick films. Following deposition, each wafer was subjected to a post-deposition bake at 100° C. for 60 seconds to complete drying of the samples. The wafers were then exposed using an ASML TwinScan NXE 3400 exposure tool by creating an array of open-frame exposure pads at different doses across the wafer. The wafers were then subjected to a post-exposure bake for 60 seconds at either 160° C. or 180° C. Following the post-exposure bake, each pad on each wafer was analyzed using FTIR spectroscopy to measure the peak areas that correspond to the absorbance of the C—H stretch (the region from 2800 cm⁻¹ to 3000 cm⁻¹) to determine the amount of carbon remaining in each pad. The measured peak areas were then normalized to the peak areas of the non-exposed regions on the same wafer to calculate a relative peak area (or normalized alkyl content). The normalized alkyl content for each sample was plotted vs. dose, as shown in FIG. 12.

As shown in FIG. 12, at both PEB temperature conditions, resist compositions comprising the additive A4 (films a and b) show less normalized alkyl content at every dose compared to the control film (c). In other words, after exposure to EUV radiation and subsequent baking, the photoresist films comprising the additive A4 lose more carbon at a given dose than photoresist films without the additive. The results show that a PEB temperature of 180° C. reduces the normalized alkyl content of the additive containing films (a and b) to asymptotic levels at a dose of about 30 mJ/cm². A PEB temperature of 160° C. causes a more gradual decrease in the normalized alkyl content of additive containing films (a and b), reaching asymptotic levels at about double the dose (about 60 mJ/cm²) of the comparative films exposed to a 180° C. PEB. FIG. 12 shows that the normalized alkyl content of the photoresist films prepared without the additive (film c) were less sensitive to PEB temperature and were also slower to achieve asymptotic levels of normalized alkyl content as compared to the PAG-additive containing films a and b. Further considering Sample 10D, the shifting of the contrast curve to the left (FIG. 11D) seems to suggest that the significant dealkylation promotes a lower dose condensation of the resist. This effect seems to not have been fully offset by the presence of the additive. The results of this study suggest that additive A4 enhances the radiolysis-induced thermolysis behavior of organotin photoresists wherein more hydrocarbon release can take place during a post-exposure thermal processing relative to non-additive containing compositions. The improvement in radiolysis induced thermolysis can therefore lead to higher resist sensitivity corresponding to a possibility of a lower dose processing.

The data presented in this example shows that the presence of a PAG additive in the photoresist can improve the efficiency of the radiolysis induced thermolysis process by improving the amount of thermolysis (i.e., release of the organic moieties from the material) during a bake process following exposure to radiation (PEB). Improved positive tone patterning in lower dose regions can be achieved, for example, with a combination of a PAG additive and sufficiently high PEB temperatures, although at high enough temperatures thermolysis can take place independent of radiation resulting in thickness loss at low dose. For this resist composition comprising PAG additive A4, positive tone patterning can be achieved at lower doses and at a 180° C. PEB temperature compared to a non-additive resist composition at the same temperature. The presence of PAG additives in an organometallic resist composition have been shown to contribute to various positive tone patterning improvements over a range of processing conditions.

### Example 3: Additive A2 and A3 Films, Patterning, and Contrast Curves

This example presents contrast curves for organotin oxide hydroxide photoresist compositions and shows the effect of incorporating a quencher additive (A2 or A3) as well as the effects of the concentration of the additive and the post-exposure bake (PEB) temperature on the processing window for positive tone development of the photoresist compositions.

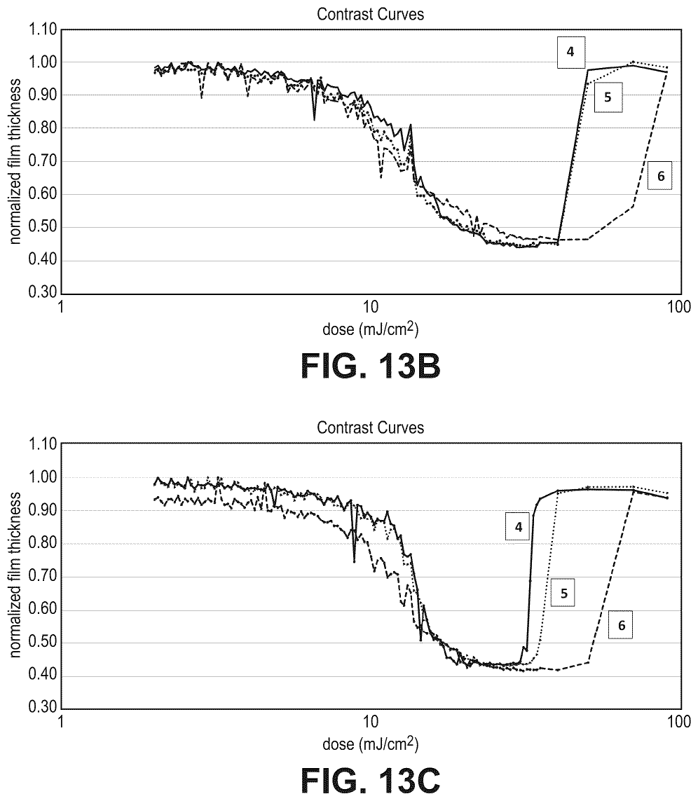

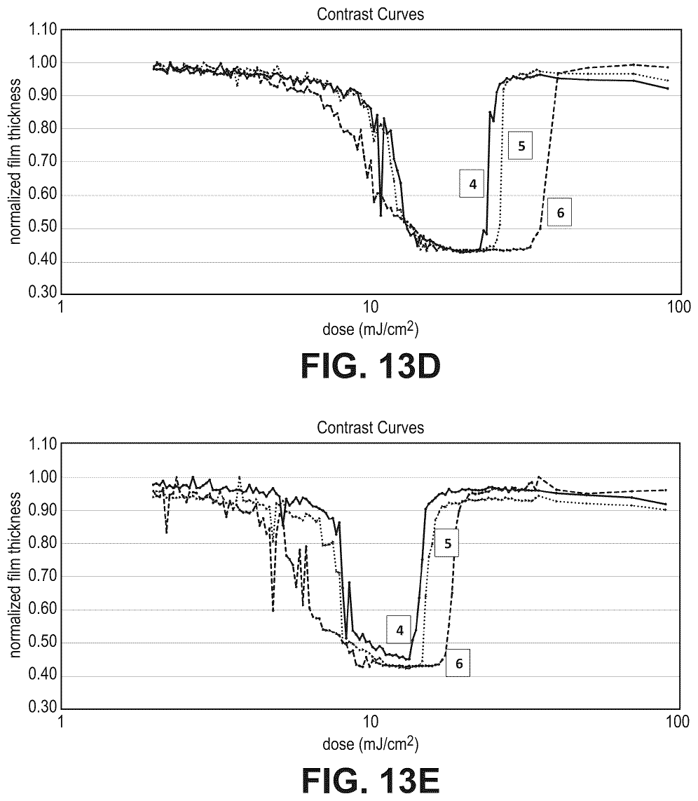

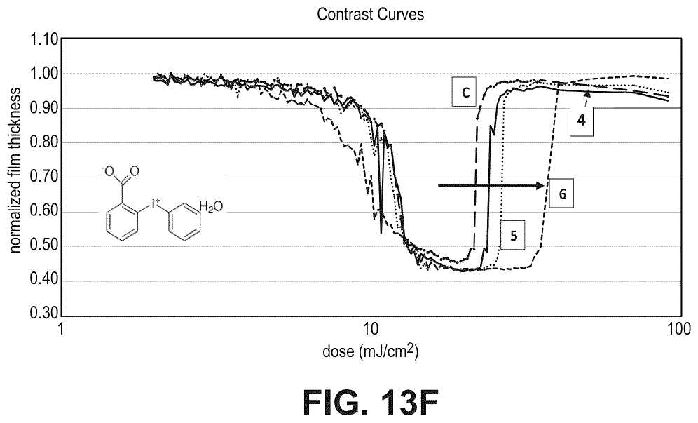

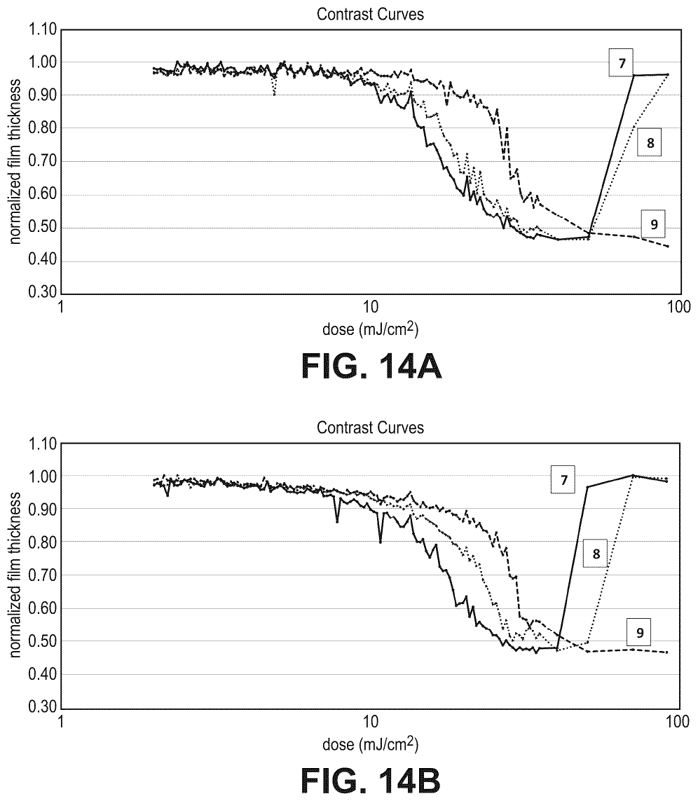

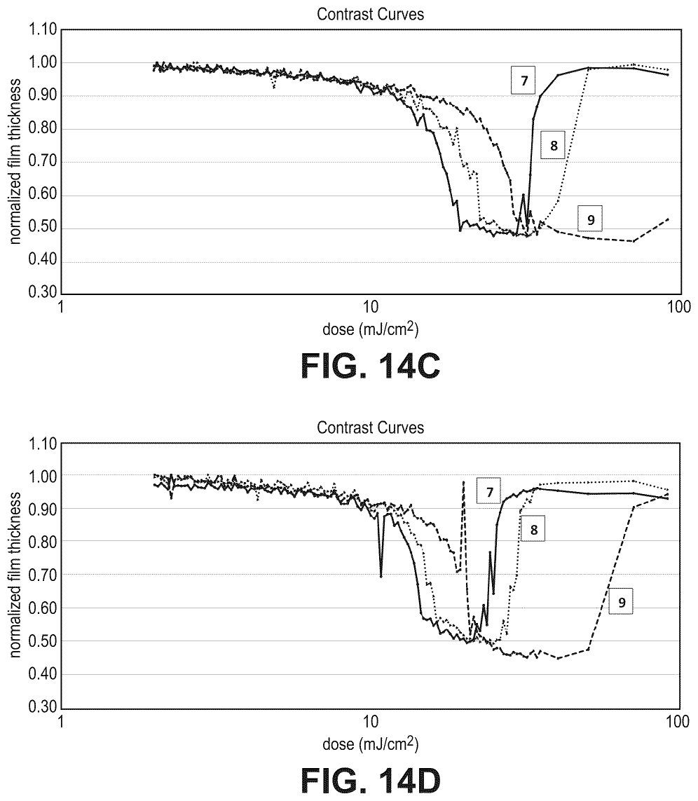

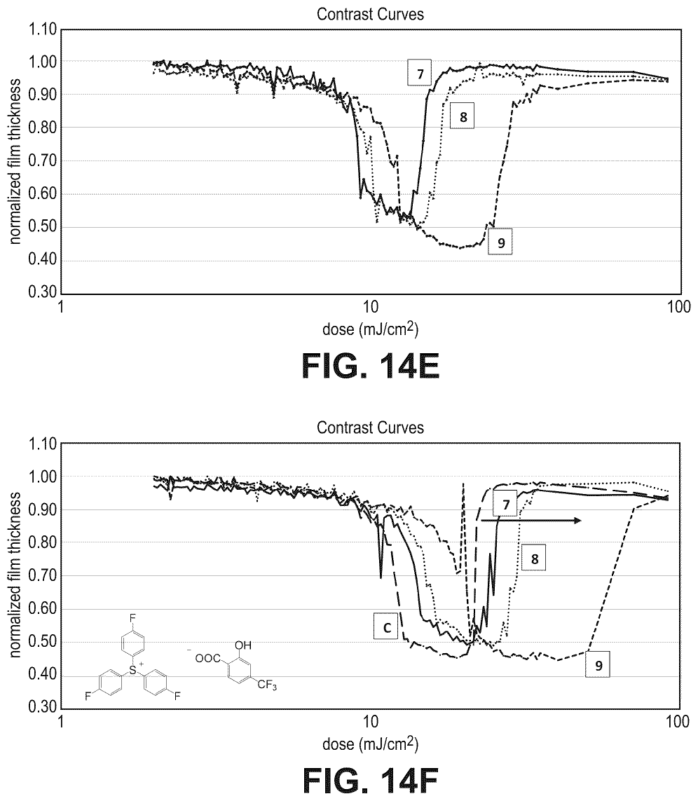

A series of photoresist films (films 4-9 and C) were prepared from samples 4-9 and C, respectively. Following deposition, the films were subjected to a PAB of 100° C. for 60 s. Following EUV exposure, each of films 4-9 was subjected to a 60 s PEB at 120° C., 140° C., 160° C., 180° C., or 200° C. Film C was subjected to a 60 s PEB at 180° C. Contrast curves were produced for each sample according to the methods described above and plotted in FIGS. 13A-13F (additive A2) and FIGS. 14A-14F (additive A3).

FIGS. 13A through 13E show contrast curves at PEB temperatures 120° C., 140° C., 160° C., 180° C., and 200° C., respectively, for films prepared from samples 4, 5, and 6. FIGS. 14A through 14E show contrast curves at PEB temperatures 120° C., 140° C., 160° C., 180° C., and 200° C., respectively, for films prepared from samples 7, 8, and 9. Considering the results for each of the PEB temperatures, it can be seen that the width of the low film thickness region of the contrast curves generally increases with increasing concentration of the additive. This indicates an increase in the solubility of the exposed film and a broadening of the processing window for positive tone patterning. Noting the logarithmic scale of the x-axis and referring to FIG. 13D, with increasing molar ratio of the additive from 0.01 (film 4) to 0.05 (film 6), the processing window broadened by approximately a factor of 3. In general, the presence of the additive increases the positive-tone process window by pushing the negative-tone transition region to a higher dose and pushing the positive-tone transition region to a lower dose.

FIG. 13F shows a contrast curve for film samples 4, 5, and 6 alongside the non-additive containing control sample C, with all of the film samples represented in FIG. 13F having been subjected to a PEB of 180° C. A broadening of the processing window was observed with increasing molar concentration ratio of the A2 additive (additive:Sn) from 0 to 0.05. The arrow in FIG. 13F indicates increasing additive concentration. This example shows that the presence of the A2 additive at even the lowest concentration ratio provided an increase in the upper range of the dose for which the exposed resist could be removed (high dose rise in the curve). The processing window improvements with the addition of the quencher additive are thought to be related to the quencher frustrating condensation of the resist, which results in the exposed resist maintaining solubility at higher doses. This increase in the higher dose processing window for positive tone patterning was most pronounced for film sample 6, the sample with the highest concentration ratio of the quencher additive. While the film sample 6 showed some reduction in contrast and some increase in top loss, the additive promoted a much wider dose window than the non-additive containing control film C.

Referring to FIG. 14F, a broadening of the processing window was observed with increasing concentration ratio of the A3 additive (additive:Sn) from 0 (film C) to 0.05 (film 9). The arrow in FIG. 14F indicates increasing additive concentration. In particular, this example shows that the presence of the A3 additive at even the lowest concentration ratio provided an increase in the upper range of the dose for which the exposed resist could be removed (high dose rise in the curve). Significantly, the A3 additive was shown to provide a wider process window (especially at the highest additive concentration ratio), while exhibiting comparable contrast to the non-additive containing film C. Noting the logarithmic scale of the x-axis the process window for film 9 was approximately 2.5 times wider than that of non-additive containing film C.

Comparing the patterning performance for A2-additive containing films (FIGS. 13A-13F) and A3-additive containing films (FIGS. 14A-14F), the results suggest that the films with the A3 additive mitigate top loss better than the film with the A2 additive. This difference is most evident at higher additive concentrations and/or lower PEB temperatures. The top loss is related to (unintended) solubility of the unexposed regions in the positive tone developer. The A3 additive has fluorinated phenyl groups and the A2 additive does not. The results suggest that the fluorinated phenyl groups on the A3 additive contribute to the mitigation of the top loss.

This study shows a clear positive correlation between increasing quencher additive concentration and the widening of the high dose processing region. The results suggest that quenchers can be used to widen the positive tone development dose window while maintaining high photoresist contrast. The results also suggest that fluorinated quenchers can be particularly useful.

### Example 4: Double Bake Double Development (DBDD) Processing

This example describes improved methods for positive-tone processing of organotin photoresists without an additive. The improved methods employ two PEB at two different temperatures and two development steps.

A set of photoresist films were prepared from precursor coating sample C. Spin-coating was used to deposit each photoresist sample to yield photoresist films of approximately 20 nm thickness, as described above. Following deposition, each wafer was subjected to a post-apply bake at 100° C. for 60 seconds to complete drying of the samples. The wafers were then exposed using an ASML TwinScan NXE 3400 exposure tool by creating an array of open-frame exposure pads at different doses across the wafer. The samples were then subjected to a first PEB for 60 seconds at a selected temperature from 100° C. to 180° C. followed by a first development with 2.38% TMAH (aq). The samples were then subjected to a second PEB for 60 seconds at a selected temperature from 100° C. to 180° C. for 60 followed by a second development with 2.38% TMAH (aq). Finally, the wafers were baked at 250° C. for 1 minute to densify the patterns.

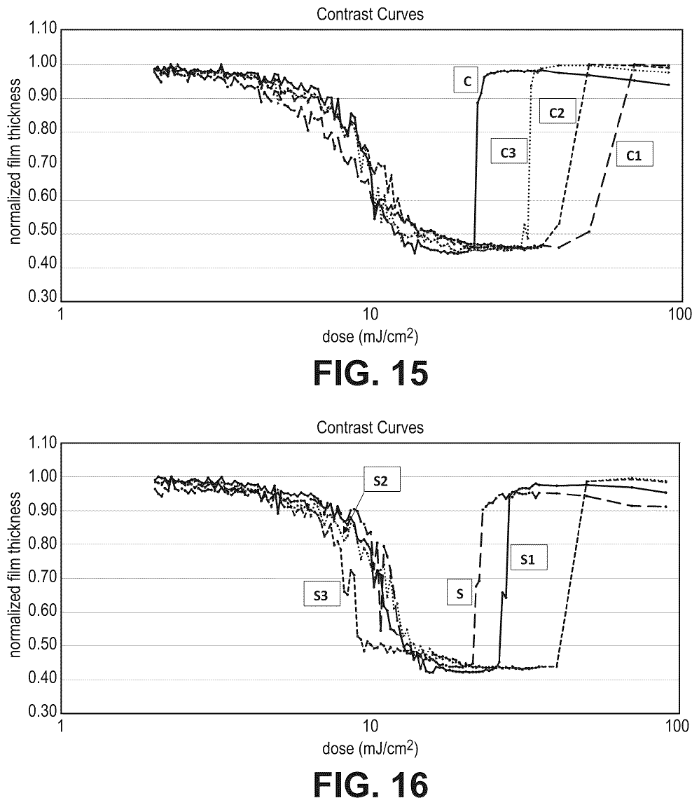

FIG. 15 shows the contrast curves for the control samples (films C1-C4) processed with a DBDD process at a first PEB temperature of 100° C. (film C1), 140° C. (film C2), or 160° C. (film C3) and a second PEB temperature of 180° C. Additionally, a contrast curve for a control sample (film C) processed with a single 180° C. PEB and development is also plotted in FIG. 15. Wider process windows were obtained for the samples processed according to the DBDD process (Films C1-C3) than for the sample processed using a single PEB and single PEB temperature (film C). Owing to the unexposed resist film's hydrophobicity and insolubility in aqueous developer, the first PEB temperature can effectively set the dose for the negative-tone transition region (at the right hand side of the contrast curve). Higher PEB temperatures and radiation doses correspond to increased degrees of condensation and densification of the oxide hydroxide network in the irradiated areas of the photoresist. Referring again to FIG. 15, the film C1, processed at a first PEB temperature of 100° C. and a second PEB at 180° C., shows a wide process window because the first development is able to remove significantly more irradiated material than for samples processed with a higher first PEB temperature. FIG. 15 also shows that the PEB temperature affects the field thickness of the exposed film, with the higher PEB temperatures having less loss of film thickness (“top loss”) in the lower dose regions as compared to film C1.

This study shows that a double bake double development process can lead to improved positive-tone process windows.

### Example 5: DBDD Processing with Additive Compositions

This example describes improved methods for positive-tone processing of organotin photoresists. The improved methods employ a combination of the use of additive-containing photoresist compositions and the use of double bake double development (DBDD) processing. The DBDD processing involves two post-exposure bake (PEB) steps at different temperatures and a development step following each PEB bake.

A set of photoresist films was prepared from precursor coating sample 5 (corresponding to additive-containing film samples S1-S3) and the control precursor coating sample C (corresponding to non-additive containing film sample S). Spin-coating was used to deposit each coating sample to yield photoresist films of approximately 20 nm thickness, as described above. Following deposition, each wafer was subjected to a post-apply bake at 100° C. for 60 seconds to complete drying of the samples. The wafers were then exposed using an ASML TwinScan NXE 3400 exposure tool by creating an array of open-frame exposure pads at different doses across the wafer. The film samples S2 and S3 were then subjected to a first PEB at 160° C. for 60 seconds followed by a first development with 2.38% TMAH (aq). The film samples S2 and S3 were then subjected to a second PEB for 60 seconds at either 180° C. (S2) or 200° C. (S3) for 60 followed by a second development with 2.38% TMAH (aq). The film samples S and S1 were subjected to a single PEB at 180° C. for 60 seconds followed by a first development with 2.38% TMAH (aq). Finally, the wafers were baked at 250° C. for 1 minute to densify the patterns from thermal driven condensation.

FIG. 16 shows the contrast curves for additive-containing film samples processed with a DBDD process at a first PEB temperature of 160° C. and a second PEB temperature of 180° C. (S2) or 200° C. (S3). FIG. 16 also shows the contrast curve for additive-containing film sample S1, processed with a single bake at 180° C. and a single development. FIG. 16 further shows the contrast curve for non-additive containing film S processed with a single bake at 180° C. and a single development. As shown in FIG. 16, the additive-containing film samples show an improved positive-tone process window when processed using the DBDD process (S2 and S3) in comparison to the non-additive containing film sample S and additive-containing film sample S1 which were processed using a single PEB and single development process. The results show that the process window can be widened for films prepared from precursor coating sample 5 using the DBDD process and a higher temperature second PEB.

The results suggest that the first PEB at 160° C. determines the solubility of the exposed material in the high dose region of the contrast curve and allows for significant removal of the irradiated material during the subsequent first development step. Furthermore, the results suggest that by performing the second PEB temperature at a higher temperature than the first PEB, the second PEB can drive further dealkylation of the exposed resist material in the lightly exposed areas. The second PEB can then facilitate further removal of such material in the second development process to result in a lowering of the dose in which the exposed material transitions from insoluble to soluble (left side of the contrast curve). The DBDD process shows improved positive-tone process windows for the additive-enhanced compositions than when the samples are processed with a single PEB and single development process.

This study shows that a double bake double development process can be effectively used to improve positive-tone processing windows for additive-enhanced organometallic photoresist compositions.

### Example 6: Positive Tone Contact Hole Patterning

This example demonstrates the use of additive-containing organometallic photoresist compositions for enhancement of patterning of contact holes. The additive in this example is quencher-type additive A2.

A set of photoresist films was prepared from precursor coating samples 4 and 5 and the control precursor coating sample C. Spin-coating was used to deposit each coating sample to yield photoresist films of approximately 20 nm thickness. Following deposition, each wafer was subjected to a post-apply bake at 100° C. for 60 seconds to complete drying of the samples. The wafers were then exposed using an ASML TwinScan NXE 3400 exposure tool to form a hexagonal array of holes on a 38 nm vertical by 66 nm horizontal pitch. The film samples were then subjected to a PEB at 160° C. or 180° C. for 60 seconds followed by development with 2.38% TMAH (aq). Finally, the wafers were baked at 250° C. for 1 minute to densify the patterns. CD-SEM images were then collected for each patterned film and analyzed to determine the dose, critical dimensions (CD) and LCDU (local critical dimension uniformity) values for each contact hole pattern. In this context, the CD value is the average diameter of the holes and LCDU is the standard deviation of the average diameter. The EUV dose for each contact hole pattern is shown as the first number in the inset of each image.

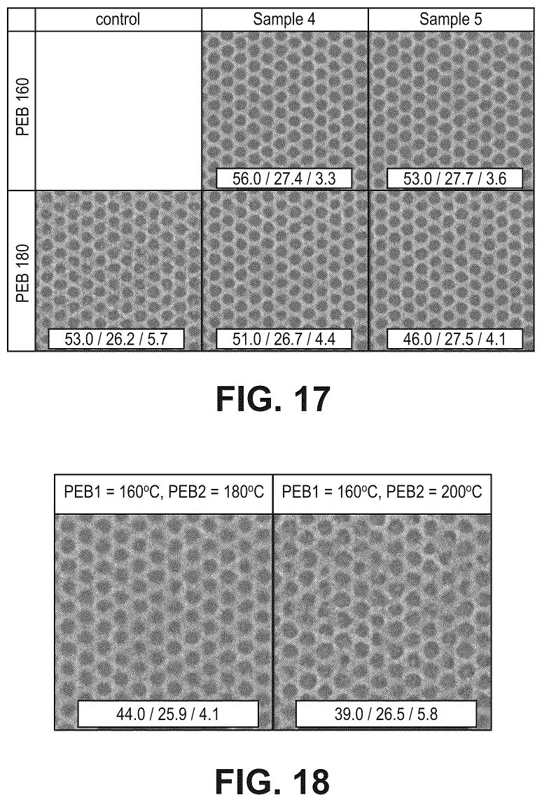

FIG. 17 shows CD-SEM images for the contact hole patterns prepared as described above. Referring to FIG. 17, the contact hole pattern under the column header “control” was prepared from the control precursor coating sample C. The contact hole patterns under the column headers “Sample 4” and “Sample 5” were prepared from precursor coating samples 4 and 5, respectively. The results show that improved sensitivity and LCDU were obtained for Samples 4 and 5 compared to the control sample. For a PEB of 180° C., the doses for Samples 4 and 5 were 51 mJ/cm² and 46 mJ/cm², respectively, compared to a dose of 53 mJ/cm² for the control sample. Similarly, the LCDU values obtained at a 180° C. PEB for the contact hole patterns made with precursor coating samples 4 and 5 (4.4 nm and 4.1 nm, respectively) were lower than for the control (5.7 nm). The results suggest that wider positive-tone process windows for the additive samples enable improved contact hole patterning via positive-tone development. Comparing the results for Samples 4 and 5 subjected to a PEB of 160° C. versus a PEB of 180° C., it is observed that while the doses for the 160° C. PEB bake are higher for both Samples 4 and 5, the LCDU values are lower. The LCDU for Sample 4 was reduced from 4.4 nm to 3.3 nm when processed at the lower PEB temperature. Similarly, the LCDU for Sample 5 was reduced from 4.1 nm to 3.6 nm when processed at the lower PEB temperature.

This example shows that positive tone patterning of contact holes can be improved with the incorporation of quenchers into organometallic resist compositions.

### Example 7: Positive Tone Contact Hole Patterning with DBDD Process

This example demonstrates the use of additive-containing organometallic photoresist compositions and double bake-double development (DBDD) processing for the enhancement of patterning of contact holes. The additive in this example is quencher-type additive A2.

A set of photoresist films was prepared from precursor coating sample 5. Spin-coating was used to deposit each coating sample to yield photoresist films of approximately 20 nm thickness. Following deposition, each wafer was subjected to a post-apply bake at 100° C. for 60 seconds to complete drying of the samples. The wafers were then exposed using an ASML TwinScan NXE 3400 exposure tool to form a hexagonal array of holes on a 38 nm vertical by 66 nm horizontal pitch. The samples were then subjected to a first PEB at 160° C. for 60 seconds followed by development with 2.38% TMAH (aq). The samples were then subjected to a second PEB at 180° C. or 200° C. for 60 seconds followed by a second development with 2.38% TMAH (aq). Finally, the wafers were baked at 250° C. for 1 minute to densify the patterns. CD-SEM images were then collected for each patterned film to determine the dose, critical dimension (CD) and LCDU values at different doses.

FIG. 18 shows the CD-SEM images and associated dose, CD, and LCDU values for the contact hole patterns obtained using the DBDD process and additive-containing photoresist films. The results show that lower doses were required to form contact hole patterns using the additive-containing photoresist film and a DBDD process compared to a conventional single PEB/single development process. For example, and referring back to FIG. 17, the control contact hole pattern (first column) was produced using the non-additive containing precursor coating sample, a single 180° C. PEB, and a single development step at a dose of 53 mJ/cm². Conversely, and as shown in FIG. 18, using the additive-containing precursor coating sample 5 in a DBDD process yields contact hole patterns at lower doses of 44 mJ/cm² for a second PEB of 180° C. and 39 mJ/cm² for a second PEB of 200° C. Furthermore, using the additive-containing precursor coating sample 5 in a DBDD process yields contact hole patterns with improved or comparable LCDU values (4.1 nm and 5.8 nm) as compared to the control sample using a single PEB and single development (5.7 nm).

This study shows that a double bake double development process can be effectively used to improve positive tone contact hole patterning of additive-enhanced organometallic photoresist compositions.

### Example 8. Positive Tone Contact Hole Patterning

This example demonstrates the use of additive-containing organometallic photoresist compositions for enhancement of patterning of contact holes.

A set of photoresist films was prepared from precursor coating samples, according to Table 4. Spin-coating was used to deposit each coating sample to yield photoresist films of approximately 20 nm thickness. Following deposition, each wafer was subjected to a post-apply bake at 100° C. for 60 seconds to complete drying of the samples. The wafers were then exposed using an ASML TwinScan NXE 3400 exposure tool to form a hexagonal array of holes on a 38 nm vertical by 66 nm horizontal pitch. The film samples were then subjected to a PEB at 160° C. or 180° C. for 60 seconds, as shown in Table 5, followed by development with 2.38% TMAH (aq). Film samples D1 and D2 were additionally subjected to a second PEB at 180° C. and 200° C., respectively, for 60 seconds followed by a second development with 2.38% TMAH (aq). Finally, the wafers were baked at 250° C. for 1 minute to densify the patterns. CD-SEM images were then collected for each patterned film and analyzed to determine the critical dimensions (CD) for each contact hole pattern. Film samples A and E were prepared without an additive. Film samples B1-D1and H1-H2 contain additive A2. Film samples F1-G2 contain additive A3.

TABLE 4

| | Precursor | | PEB 1 | PEB 2 |
|---|---|---|---|---|
| | Coating | | temperature, | temperature, |
| Film Sample | Sample | Additive | C. | C. |
| A | C | none | 180 | N/A |
| | (control) | | | |
| B1 | 4 | A2 | 180 | N/A |
| B2 | 4 | A2 | 160 | N/A |
| C1 | 5 | A2 | 180 | N/A |
| C2 | 5 | A2 | 160 | N/A |
| D1 | 5 | A2 | 160 | 180 |
| D2 | 5 | A2 | 160 | 200 |
| E | C | none | 180 | N/A |
| | (control) | | | |
| F1 | 9b | A3 | 180 | N/A |
| F2 | 9b | A3 | 160 | N/A |
| G1 | 9 | A3 | 180 | N/A |
| G2 | 9 | A3 | 160 | N/A |
| H1 | 6b | A2 | 180 | N/A |
| H2 | 6b | A2 | 160 | N/A |

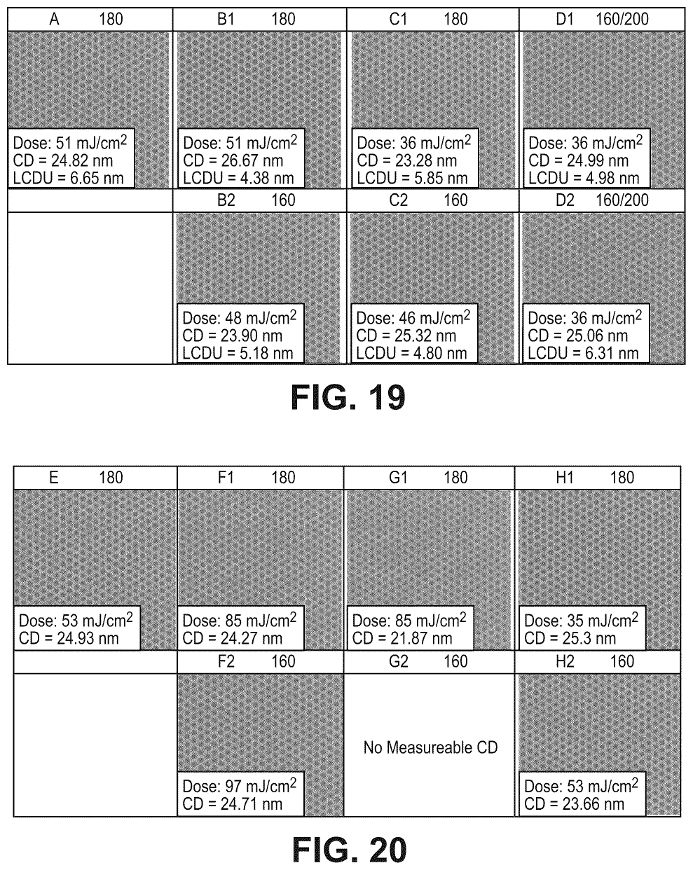

FIGS. 19 and 20 show CD-SEM images of the final patterned film products and Table 5 summarizes the dose and measured CD values for each patterned film. The additive-containing films generally resulted in contact holes with more clearing within the holes and an absence of shrinkage as compared to the non-additive containing films (A and E). In particular, the images of samples B1 and H1 show a combination of enhanced clearing of the holes, lower dose, and lower line width roughness as compared to their respective non-additive control samples (A and E) processed at the same conditions. D1 and D2 (FIG. 15) show CD-SEM images of patterns which were formed with a second bake and a second development after the first bake and the first development. In both cases the second bake was at a higher temperature than the first bake. Comparing C1 (PEB 180° C.) with D1 (PEB 160° C./PEB 180° C.) where both samples were exposed at a dose of 36 mJ/cm², it can be seen from the increase in the CD from 23.28 nm to a CD of 24.99 and the decrease in the LCDU from 5.85 nm to 4.98 nm that the double bake-double development process can lower the patterning dose and can aid in clearing the contact holes. This result suggests that the first, lower temperature PEB lightly condenses exposed material which is then removed in the first development step, while the second, higher temperature PEB further condenses remaining exposed material which is then removed in the second development step. This double bake-double development process seems to render more of the exposed material soluble, as evidenced by the improvement of the hole clearing of D1 as compared to C1.

TABLE 5

| | EUV Dose, | |
|---|---|---|
| Film Sample | mJ/cm² | CD, nm |
| A | 51 | 24.82 |
| B1 | 51 | 26.67 |
| B2 | 48 | 23.90 |
| C1 | 36 | 23.28 |
| C2 | 46 | 25.32 |
| D1 | 36 | 24.99 |
| D2 | 36 | 25.06 |
| E | 53 | 24.93 |
| F1 | 85** | 24.27 |
| F2 | 97 | 24.71 |
| G1 | 85 | 21.87 |
| G2 | >100 | — |
| H1 | 35 | 25.3 |
| H2 | 53 | 23.66 |

The results of this study are particularly noteworthy since they show that quenchers can be used to effectively realize inherent processing advantages of patterning contact holes using positive tone development. That is, development of a latent image of contact holes with positive tone patterning involves the exposure of a regular pattern of holes and the clearing of exposed material from the regular pattern of holes, which is less prone to defects than negative tone patterning of contact holes.

This example shows that positive tone patterning of contact holes can be improved with the incorporation of quenchers into organometallic resist compositions.

### Further Inventive Concepts

A1. A method for patterning a radiation sensitive material on a substrate, the method comprising:
a. developing a material on a substrate based on a latent image in the material with irradiated regions and non-irradiated regions to form a physically patterned material on the substrate, wherein the developing comprises contact of the material with a first liquid developer, the material prior to irradiation comprising RₙSnOₓ(OH)₄₋ₙ₋₂ₓ 0.5≤n<3, 0<x<1.5, wherein R comprises a hydrocarbyl ligand having from 1-31 carbon atoms, wherein the substrate with the latent image received a post exposure bake at a first temperature at least about 45° C. and wherein the developing comprises selective removal of the irradiated regions or the non-irradiated regions to form a first patterned structure;
b. heating the first patterned structure at a second temperature at least about 5° C. greater than the first temperature for at least about 0.1 minute to form a second baked structure, and
c. developing the second baked structure comprising contact with a second liquid developer, wherein the second liquid developer comprises an acid or a base.

A2. The method of inventive concept A1 wherein the first liquid developer comprises an organic solvent or aqueous alkaline liquid.

A3. The method of inventive concept A1 where in the first liquid developer and/or the second liquid developer comprises a quaternary ammonium hydroxide composition.

A4. The method of inventive concept A3 wherein the first liquid developer and the second liquid developer independently comprise from about 0.5 to about 30 weight percent of the quaternary ammonium hydroxide composition.

A5. The method of inventive concept A1 wherein the first liquid developer and/or the second liquid developer comprises tetramethyl ammonium hydroxide (TMAH).

A6. The method of inventive concept A1 wherein the first liquid developer and the second liquid developer have the same composition.

A7. The method of inventive concept A1 wherein the second liquid developer is different from the first liquid developer.

A8. The method of inventive concept A1 wherein contacts of the material with the first liquid developer and with the second liquid developer are independently performed for a period of about 5 seconds to about 30 minutes.

A9. The method of inventive concept A1 wherein the second temperature is from about 145° C. to about 225° C.

A10. The method of inventive concept A1 wherein the heating at the second temperature is performed for about 0.1 minute to about 10 minutes.

A11. The method of inventive concept A1 further comprising, prior to developing, heating the material on a substrate based on a latent image in the material at a first temperature from about 80° C. to about 200° C.

A12. The method of inventive concept A11 wherein the heating at the first temperature is performed for about 0.1 minute to about 10 minutes.

A13. The method of inventive concept A11 wherein the second temperature is from 10° C. greater to 100° C. greater than the first temperature.

A14. The method of inventive concept A1 wherein R comprises a methyl ligand, an i-propyl ligand, a t-butyl ligand, a t-amyl ligand or a combination thereof.

A15. The method of inventive concept A1 wherein the hydrocarbyl ligand is branched and/or wherein the hydrocarbyl ligand comprises unsaturated bonds, aryl groups, and/or heteroatoms.

A16. The method of inventive concept A1 wherein the hydrocarbyl ligand is substituted with one or more fluorine atoms and/or iodine atoms.

A17. The method of inventive concept A1 wherein R comprises a mixture of different hydrocarbyl ligands, each independently having from 1-31 carbon atoms.

A18. The method of inventive concept A1 wherein the material comprises an organotin oxide hydroxide network.

A19. The method of inventive concept A1 wherein the material comprises a composition represented by the formula RSnOₓ(OH)₃₋₂ₓ wherein 0<x<1.5.

A20. The method of inventive concept A1 further comprising an additive (A) in a molar ratio of A:Sn from about 0.002 to about 2, wherein the additive comprises a photoacid generator, a quencher or a mixture thereof, wherein the additive comprises an onium ion or zwitterion.

A21. The method of inventive concept A20 wherein the additive comprises an electron trapping agent.

A22. The method of inventive concept A20 wherein the additive comprises an aromatic group and/or a fluorinated group.

A23. The method of inventive concept A20 wherein the onium ion comprises a cation formed from group 15 to group 17 core atoms.

A24. The method of inventive concept A20 wherein the onium ion comprises an iodonium cation, a sulfonium cation, an ammonium cation, a phosphonium cation or combinations thereof.

A25. The method of inventive concept A20 wherein the additive comprises an organoiodonium hydroxide compound, an organosulfonium hydroxide compound or combinations thereof.

A26. The method of inventive concept A20 wherein the additive is capable of absorbing secondary electrons and/or UV radiation to produce a soluble reaction product.

A27. The method of inventive concept A20 wherein the additive is does not significantly decrease absorption of EUV radiation by the organotin composition.

A28. The method of inventive concept A20 wherein the additive has organic functional groups and wherein the additive is hydrophobic.

A29. The method of inventive concept A20 wherein the additive is soluble in at least some organic solvents.

A30. The method of inventive concept A20 wherein the additive comprises a composition represented by the formula:

A31. The method of inventive concept A20 wherein the additive comprises a composition represented by the formula:

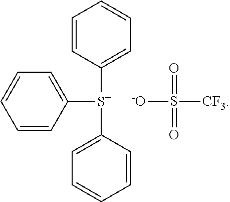

A32. The method of inventive concept A20 wherein the additive comprises a composition represented by the formula:

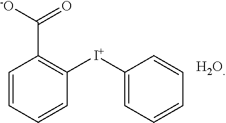

A33. The method of inventive concept A20 wherein the additive comprises a composition represented by the formula:

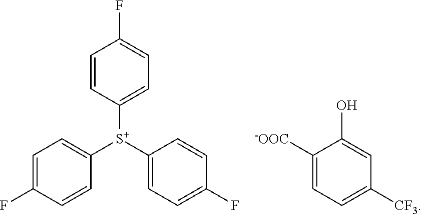

A34. The method of inventive concept A20 wherein A:Sn is from about 0.002 to about 0.4.

A35. The method of inventive concept A1 wherein the physically patterned material on the substrate comprises a line/space pattern having a half-pitch of less than 25 nm or a pattern of holes on a grid having a CD of less than 35 nm.

A36. The method of inventive concept A20 wherein the additive comprises a quencher and wherein the physically patterned material on the substrate comprises a pattern of holes on a grid having a CD of less than 30 nm and a LCDU of less than about 6 nm.

A37. The method of inventive concept A36 wherein the additive comprises an organoiodonium hydroxide compound, an organosulfonium hydroxide compound or combinations thereof.

A38. The method of inventive concept A1 further comprising, prior to developing, exposing the radiation sensitive material on a substrate to a pattern of EUV radiation to form the latent image in the material.

A39. The method of inventive concept A38 wherein the radiation has a dose from about 1 mJ/cm² to about 100 mJ/cm² and wherein the substrate comprises a silicon wafer.

B1. A precursor solution for forming an organometallic radiation patterning material, the precursor solution comprising an organic solvent, a dissolved organotin composition having C—Sn bonds that can cleave in response to EUV radiation, and a quencher, wherein the precursor solution has a tin concentration from about 0.001 M to about 1 M and the quencher (A) in a molar ratio of A:Sn from about 0.002 to about 2, and wherein the quencher comprises an onium cation and an anion that is a conjugate base to a weak acid.

B2. The precursor solution of inventive concept B1 wherein the dissolved organotin composition is represented by the formula RₙSn(L₄₋ₙ), n=0.5-3, wherein L₄₋ₙ represents an appropriate number of ligands that are hydroxyl, oxo, or hydrolysable ligands providing a total of 4-n valance bonds to the tin atom.

B3. The precursor solution of inventive concept B2 wherein R comprises a hydrocarbyl ligand having from 1-31 carbon atoms.

B4. The precursor solution of inventive concept B2 wherein R comprises a methyl ligand, an i-propyl ligand, a t-butyl ligand, a t-amyl ligand or a combination thereof.

B5. The precursor solution of inventive concept B3 wherein the hydrocarbyl ligand is branched and/or wherein the hydrocarbyl ligand comprises unsaturated bonds, aryl groups, and/or heteroatoms.

B6. The precursor solution of inventive concept B3 wherein the hydrocarbyl ligand is substituted with one or more fluorine atoms and/or iodine atoms.

B7. The precursor solution of inventive concept B2 wherein R comprises a mixture of different hydrocarbyl ligands, each independently having from 1-31 carbon atoms.

B8. The precursor solution of inventive concept B2 wherein n is approximately 1.

B9. The precursor solution of inventive concept B2 wherein the hydrolysable ligands comprise a dialkylamide, an alkoxide, an acetylide, or a carboxylate.

B10. The precursor solution of inventive concept B2 wherein the hydrolysable ligands comprise t-amyl oxide.

B11. The precursor solution of inventive concept B1 wherein the quencher is soluble in the organic solvent.

B12. The precursor solution of inventive concept B1 wherein the quencher comprises an electron trapping agent.

B13. The precursor solution of inventive concept B1 wherein the quencher comprises an aromatic group.

B14. The precursor solution of inventive concept B1 wherein the quencher comprises a fluorinated group.

B15. The precursor solution of inventive concept B1 wherein the onium cation comprises a cation formed from group 15 to group 17 core atoms and wherein the weak acid is a carboxylic acid so that the base is a carboxylate.

B16. The precursor solution of inventive concept B1 wherein the onium cation comprises an iodonium cation, a sulfonium cation, an ammonium cation, a phosphonium cation or combinations thereof.

B17. The precursor solution of inventive concept B1 wherein the quencher has organic functional groups and wherein the quencher is hydrophobic.

B18. The precursor solution of inventive concept B1 wherein the quencher comprises a composition represented by the formula:

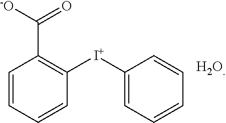

B19. The precursor solution of inventive concept B1 wherein the quencher comprises a composition represented by the formula:

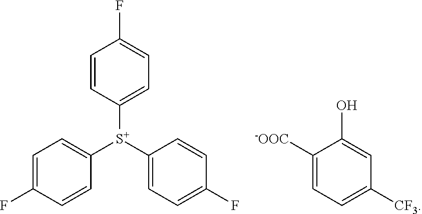

B20. The precursor solution of inventive concept B1 wherein A:Sn is from about 0.002 to about 0.4.

B21. The precursor solution of inventive concept B1 wherein the organic solvent comprises an alcohol or blends thereof.

B22. The precursor solution of inventive concept B1 wherein the organic solvent comprises 4-methyl-2-pentanol, 1-propanol, or a blend thereof.

B23. The precursor solution of inventive concept B1 further comprising a photoacid generator.

C1. A radiation patternable structure comprising a substrate and a radiation sensitive material on the substrate, the radiation sensitive material comprising a composition represented by the formula RₙSnOₓ(OH)₄-n-2x 0.5≤n<3, 0<x<1.5, and a quencher (A) in a molar ratio of A:Sn from about 0.002 to about 2, and wherein the quencher comprises an onium cation and an anion that is a conjugate base to a weak acid.

C2. The radiation patternable structure of inventive concept C1 wherein the quencher comprises an electron trapping agent.

C3. The radiation patternable structure of inventive concept C1 wherein the quencher comprises an aromatic group.

C4. The radiation patternable structure of inventive concept C1 wherein the quencher comprises a fluorinated group.

C5. The radiation patternable structure of inventive concept C1 wherein the radiation sensitive material further comprises a photoacid generator.

C6. The radiation patternable structure of inventive concept C1 wherein the onium cation comprises a cation formed from group 15 to group 17 core atoms.

C7. The radiation patternable structure of inventive concept C1 wherein the onium cation comprises an iodonium cation, a sulfonium cation, an ammonium cation, a phosphonium cation or combinations thereof.

C8. The radiation patternable structure of inventive concept C1 wherein the quencher is capable of absorbing secondary electrons and/or UV radiation to produce a soluble reaction product.

C9. The radiation patternable structure of inventive concept C1 wherein the quencher is does not significantly decrease absorption of EUV radiation by the organotin composition.

C10. The radiation patternable structure of inventive concept C1 wherein the quencher has organic functional groups and wherein the quencher is hydrophobic.

C11. The radiation patternable structure of inventive concept C1 wherein the quencher is soluble in at least some organic solvents.

C12. The radiation patternable structure of inventive concept C1 wherein the quencher comprises a composition represented by the formula:

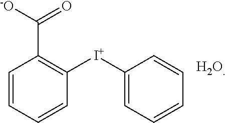

C13. The radiation patternable structure of inventive concept C1 wherein the quencher comprises a composition represented by the formula:

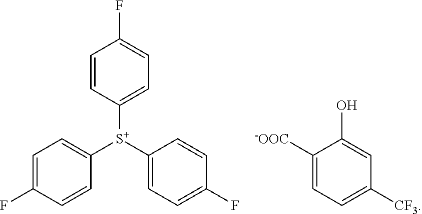

C14. The radiation patternable structure of inventive concept C1 wherein R comprises a hydrocarbyl ligand having from 1-32 carbon atoms.

C15. The radiation patternable structure of inventive concept C1 wherein R comprises a methyl ligand, an i-propyl ligand, a t-butyl ligand, a t-amyl ligand or a combination thereof.

C16. The radiation patternable structure of inventive concept C14 wherein the hydrocarbyl ligand is branched and/or wherein the hydrocarbyl ligand comprises unsaturated bonds, aryl groups, and/or heteroatoms.

C17. The radiation patternable structure of inventive concept C14 wherein the hydrocarbyl ligand is substituted with one or more fluorine atoms and/or iodine atoms.

C18. The radiation patternable structure of inventive concept C1 wherein R comprises a mixture of different hydrocarbyl ligands, each independently having from 1-31 carbon atoms.

C19. The radiation patternable structure of inventive concept C1 wherein the radiation sensitive material comprises an organotin oxide hydroxide network.

C20. The radiation patternable structure of inventive concept C1 wherein the radiation sensitive material on the substrate comprises a composition represented by the formula RSnOₓ(OH)₃₋₂ₓ wherein 0<x<1.5.

C21. The radiation patternable structure of inventive concept C1 wherein A:Sn is from about 0.005 to about 0.5.

C22. The radiation patternable structure of inventive concept C1 wherein the radiation sensitive material on the substrate has an average thickness from about 1 nm to about 50 nm and wherein the substrate comprises a silicon wafer.

In the above disclosure, it should be understood that certain terms are used interchangeably with each other. For example, one of ordinary skill in the art will understand that the terms “coating”, “layer”, and “film” are meant to construe the same idea, unless explicitly stated otherwise.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understood that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. As would be understood by a person of ordinary skill in the art, the use of the term “about” herein refers to measurement error for the particular parameter unless explicitly indicated otherwise.

What is claimed is:

1. A method for patterning a radiation sensitive material on a substrate, the method comprising:
developing a material on a substrate based on a latent image in the material with irradiated regions and non-irradiated regions to form a physically patterned material on the substrate, wherein the developing comprises contact of the material with an aqueous alkaline liquid, the material prior to irradiation comprising an organotin composition represented by RₙSnOₓ(OH)₄₋ₙ₋₂ₓ, 0.5≤n<3, 0<x<1.5, wherein R comprises a hydrocarbyl ligand having from 1-31 carbon atoms, and an additive (A) in a molar ratio of A:Sn from about 0.002 to about 2, and wherein the additive comprises a photoacid generator, a quencher or a mixture thereof, wherein the additive comprises an onium ion or zwitterion and wherein the developing comprises selective removal of the irradiated regions.

2. The method of claim 1 wherein the additive comprises an electron trapping agent.

3. The method of claim 1 wherein the additive comprises an aromatic group.

4. The method of claim 1 wherein the additive comprises a fluorinated group.

5. The method of claim 1 wherein the onium ion comprises a cation formed from group 15 to group 17 core atoms.

6. The method of claim 1 wherein the onium ion comprises an iodonium cation, a sulfonium cation, an ammonium cation, a phosphonium cation or mixture thereof.

7. The method of claim 1 wherein the additive comprises an organoiodonium hydroxide compound, an organosulfonium hydroxide compound or mixture thereof.

8. The method of claim 1 wherein the additive is capable of absorbing secondary electrons and/or UV radiation to produce a soluble reaction product.

9. The method of claim 1 wherein the additive does not significantly decrease absorption of EUV radiation by the organotin composition.

10. The method of claim 1 wherein the additive has organic functional groups and wherein the additive is hydrophobic.

11. The method of claim 1 wherein the additive is soluble in at least some organic solvents.

12. The method of claim 1 wherein the additive comprises a composition represented by the formula:

[symbol]

13. The method of claim 1 wherein the additive comprises a composition represented by the formula:

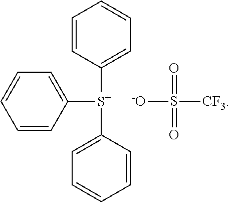

14. The method of claim 1 wherein the additive comprises a composition represented by the formula:

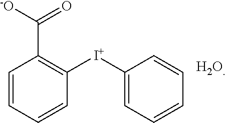

15. The method of claim 1 wherein the additive comprises a composition represented by the formula:

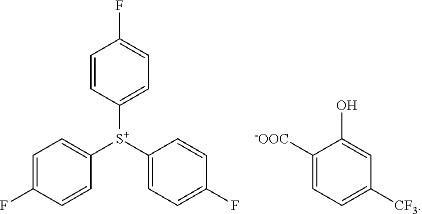

16. The method of claim 1 wherein the aqueous alkaline liquid comprises a quaternary ammonium hydroxide composition.

17. The method of claim 16 wherein the aqueous alkaline liquid comprises from about 0.5 to about 30 weight percent of the quaternary ammonium hydroxide composition.

18. The method of claim 1 wherein the aqueous alkaline liquid comprises tetramethyl ammonium hydroxide (TMAH).

19. The method of claim 1 wherein contact of the material with the or aqueous alkaline liquid is performed for a period of about 5 seconds to about 30 minutes.

20. The method of claim 1 wherein R comprises a methyl ligand, an i-propyl ligand, a t-butyl ligand, a t-amyl ligand or a combination thereof.

21. The method of claim 1 wherein the hydrocarbyl ligand is branched and/or wherein the hydrocarbyl ligand comprises unsaturated bonds, aryl groups, and/or heteroatoms.

22. The method of claim 1 wherein the hydrocarbyl ligand is substituted with one or more fluorine atoms and/or iodine atoms.

23. The method of claim 1 wherein 0.75<n<2 and R comprises a mixture of different hydrocarbyl ligands, each independently having from 1-31 carbon atoms.

24. The method of claim 1 wherein the material in the non-irradiated region comprises an organotin oxide hydroxide network.

25. The method of claim 1 wherein the material comprises a composition represented by the formula RSnOₓ(OH)₃₋₂ₓ wherein 0<x<1.5.

26. The method of claim 1 wherein A:Sn is from about 0.005 to about 0.4.

27. The method of claim 1 wherein the material received a post exposure bake at a temperature of at least about 80° C. prior to developing.

28. The method of claim 1 further comprising, prior to developing, heating the material on a substrate based on a latent image in the material at a temperature of from about 120° C. to about 225° C.

29. The method of claim 1 further comprising, prior to developing, exposing the radiation sensitive material on a substrate to a pattern of EUV radiation to form the latent image in the material.

30. The method of claim 29 wherein the radiation has a dose from about 1 mJ/cm² to about 100 mJ/cm².

31. The method of claim 1 wherein the physically patterned material on the substrate comprises a line/space pattern having a half-pitch of less than about 25 nm or a pattern of holes on a grid having a CD of less than about 35 nm, wherein the substrate comprises a silicon wafer.

32. The method of claim 1 wherein the additive comprises a photoacid generator.

33. The method of claim 1 wherein the additive comprises a quencher.

34. The method of claim 1 wherein the additive comprises a photoacid generator and a quencher.
